(19) United States
(12) Patent Application Publication
(10) Pub. No.: US 2017/0288123 A1
(43) Pub. Date: Oct. 5, 2017

(54) PIEZOELECTRIC DEVICE AND METHOD FOR MANUFACTURING THE SAME

(71) Applicant: NIHON DEMPA KOGYO CO., LTD., Tokyo (JP)

(72) Inventors: Makoto HATANO, Saitama (JP); Kenichi KIKUCHI, Saitama (JP); Hiroyuki SASAKI, Saitama (JP); Toshimasa TSUDA, Saitama (JP)

(73) Assignee: NIHON DEMPA KOGYO CO., LTD., Tokyo (JP)

(21) Appl. No.: 15/510,697

(22) PCT Filed: Jul. 31, 2015
(86) PCT No.: PCT/JP2015/071783

§ 371 Date: Mar. 13, 2017

(30) Foreign Application Priority Data
Sep. 19, 2014 (JP) 2014-190708
Mar. 13, 2015 (JP) 2015-050253

(51) Int. Cl. H01L 41/047; H03H 3/08; H03H 9/145; H01L 41/297; H03H 9/25; H03H 9/02

(52) U.S. Cl. CPC H01L 41/0471; H01L 41/0475; H03H 9/25; H03H 9/02992; H03H 9/14538; H01L 41/297; H03H 3/08

(57) ABSTRACT

A lead-out wiring, which is connected to a comb-shaped electrode formed on a principal surface of a piezoelectric substrate and is disposed to extend to an outer edge of the piezoelectric substrate an outer surrounding wall layer, which is arranged surrounding an outer periphery of the piezoelectric substrate including the lead-out wiring and forms a hollow portion that serves as an operation space for the comb-shaped electrode, and a top board, which bridges the outer surrounding wall layer to seal the hollow portion, are included.

### TECHNICAL FIELD

The present invention relates to a piezoelectric device, in particular, relates to the piezoelectric device, such as a surface acoustic wave (SAW) device and an oscillator, appropriate for high-density packaging equipment, such as a mobile phone, and a method for manufacturing the same.

### BACKGROUND ART

A structure of a piezoelectric device of this type will be described using a SAW device as an example. The SAW device requires securing an operation space (a hollow portion, or also referred to as a cavity) in which electrodes oscillate by a piezoelectric effect in its package. The SAW device needs to secure a predetermined cavity in a peripheral area of its comb-shaped electrode portion (an IDT electrode portion). A piezoelectric device, such as a crystal unit and an oscillator using a crystal element or similar element, similarly requires securing an operation space for its crystal element. While the following describes the SAW device as an example, the present invention is applicable to other piezoelectric devices, such as a crystal unit and an MEMS resonator.

In a conventional SAW device, to ensure its downsizing and low-profile, a SAW element chip is flip-chip bonded (face down bonding) to a wiring board using a gold (Au) bump or a solder bump, and the whole SAW element chip is sealed with a resin or similar material, to configure a compact package device of the SAW device.

Furthermore, as the SAW device, a microminiaturized packaged SAW device in chip size is proposed. The microminiaturized packaged SAW device in chip size is constituted by forming a predetermined hollow portion in the peripheral area of the comb-shaped electrode portion as a main operation portion, entirely sealing a collective piezoelectric substrate (a wafer on which a plurality of chips are formed) at a side of the comb-shaped electrodes with the resin with this hollow portion kept, and after forming external connection electrodes, dividing into individual SAW devices by dicing.

For example, in the SAW device disclosed in Patent Document 1, a void (a hollow portion) forming layer (an outer surrounding wall) made of a photosensitive resin is formed on a top surface of a SAW chip (a piezoelectric substrate) on which a comb-shaped electrode is formed, and a sealing layer (a ceiling portion) is laminated and sealed over this void forming layer, to form a void (a hollow portion) in a peripheral area of the comb-shaped electrodes.

In the SAW device disclosed in Patent Document 2, a cover includes a through electrode facing a SAW chip (a piezoelectric substrate) in which comb-shaped electrodes are formed. The cover is joined and sealed via a metal bonding portion to form a hollow portion that houses the comb-shaped electrodes between the SAW chip and the cover.

Furthermore, the SAW device disclosed in Patent Document 3 includes a SAW element as a main operation layer portion disposed on a surface of a piezoelectric substrate, a first resin portion that includes a hollow portion on this SAW element, a second resin portion on this first resin portion. This second resin portion is added with silica filler to increase elastic modulus of the second resin portion (a ceiling portion) to improve a mechanical strength such that a deflection is hard to be generated. In Patent Document 4, a resin plate mixed with mica, which is an inorganic material, as filler is used for a ceiling layer that seals a hollow portion storing a SAW element.

FIG. 35 is a cross-sectional drawing describing a structural example of a SAW device of a wafer-level chip-scale (size) package type. FIG. 36 is an explanatory drawing of a state where the SAW device illustrated in FIG. 35 is surface mounted to a mounting substrate. On a principal surface of a piezoelectric substrate 1, comb-shaped electrodes 2 are formed. Around the comb-shaped electrodes 2 are surrounded by outer surrounding wall layer 6 made of a resin to form a hollow portion (a chamber). An opening of the hollow portion is covered and sealed with a top board 7.

The outer surrounding wall layer 6 includes a plurality of openings. In these openings, electrode columns 4 are formed by plating treatment. Bases of these electrode columns 4 are electrically connected to lead-out wirings 3 of the comb-shaped electrodes 2. On top portions of the electrode columns 4, mounting terminals (such as solder balls or solder bumps) 5 are formed. The mounting terminals 5 are disposed such that their top portions are higher than the top board 7, which forms the hollow portion.

The mounting terminal 5 is formed by printing a solder bump on the electrode column 4, which is formed by performing electrolysis plating of Cu and electroless plating of Au/Ni. Mounting the SAW device onto the mounting substrate illustrated in FIG. 22 is performed by using the mounting terminal 5 as illustrated in FIG. 36. Mounting is performed by connecting the mounting terminal 5 to a terminal pad of a wiring pattern disposed on a mounting substrate 8. Thus, forming of the mounting terminal 5 requires a plurality of steps.

FIG. 37 is a plan view of a main part that describes problems of the top board that seals the hollow portion housing the comb-shaped electrodes. FIG. 37A illustrates a state where a crystal wafer on which a plurality of SAW devices are formed is covered and a heat resistant resin plate material 7′ is laminated. Reference numerals 26 indicate cutting-plane lines (cut lines) for separating into individual chips at a final step. FIG. 37A is an enlarged view that corresponds to one SAW device in FIG. 37A. The heat resistant resin plate material 7′ is mixed with a photosensitive binder. As the heat resistant resin plate material 7′, while a thermosetting resin plate material of a polyimide-base, which features low gas emission, is preferable, other heat resistant resin materials having a similar feature can also be used.

The heat resistant resin plate material 7′ in FIG. 37A is mixed with an appropriate amount of optical transparent mica as the filler in order to improve the mechanical strength to reduce the deflection and keep the hollow portion that houses the comb-shaped teeth. An exposure mask is disposed in an upper portion of the heat resistant resin plate material 7′ laminated after covering the wafer. By a technique using a photolithographic process, which performs a development by irradiating with actinic rays, preferably ultraviolet rays, openings 4′ for disposing the electrode columns 4 (see FIG. 36) are formed as illustrated in FIG. 37B.

However, in the above-described photolithographic process, an uneven shape or a non-uniform distribution of the filler mixed in the resin plate possibly generates an uneven light transmission amount to cause an inaccurate transfer of an opening pattern of the exposure mask and possibly causes a residue of the filler to project from an opening wall. Thus, the opening possibly has an irregular formed edge as illustrated in FIG. 24B. In such case, the electrode column and a plating pattern are not accurately formed.

FIG. 38 is a process view describing one exemplary process for manufacturing a substrate built-in component that includes an electronic component in a substrate. In response to a demand of downsized and thinned electronic equipment, such as a mobile terminal, a method for embedding and integrating an electronic component inside a mounting substrate has been developed. In FIG. 38, a component embedding substrate 20 has a depressed portion in which the electronic component is to be embedded to be mounted (a). In this depressed portion, an electronic component 21 is housed with a posture having component terminals 22 facing an open end of the depressed portion (FIG. b). Then, a resin 23 is casted in the depressed portion to embed the electronic component 21 (c). At positions of the component terminals 22, openings 24 reaching these component terminals 22 are opened (d). Performing electrical Cu plating in the openings 24 forms electrode columns 25 (e).

While with this method, the connection to the mounting terminals of the component is made by the electrical Cu plating, due to a poor compatibility with solder, a solder bump cannot be used. With a current structure, changing positions of the mounting terminals is difficult. Thus, it is not suitable for using as a part built-in component.

### CITATION LIST

### Patent Document

Patent Document 1: Japanese Unexamined Patent Application Publication No. 2006-108993

Patent Document 2: Japanese Unexamined Patent Application Publication No. 2006-197554

Patent Document 3: Japanese Unexamined Patent Application Publication No. 2007-142770

Patent Document 3: Japanese Unexamined Patent Application Publication No. 2011-147098

### DISCLOSURE OF THE INVENTION

### Problems to be Solved by the Invention

As described above, a mounting terminal with a structure described in FIG. 35 has many numbers of formation steps to cause the cost to increase. As described in FIG. 37, with the one that uses a resin plate mixed with filler as a top board and forms an opening for a component terminal by the photolithographic process, patterning of the opening is not accurately performed. With the terminal structure illustrated in FIG. 38, changing position of its component terminal is difficult. Therefore, there occurs a case where a desire of a customer is not satisfied.

When this type of piezoelectric component is mounted in a substrate for mounting or similar substrate by transfer molding or similar method at a customer site to be used, for example, for a module, a pressure from 5 MPa to 15 MPa is usually applied to this piezoelectric component. Accordingly, in the case where a void (a hollow portion) forming layer and a sealing layer of the SAW device described in Patent Document 1 is constituted of an organic material only, a resin layer constituting the top board should be made thick or constituted of a hard material; otherwise, when resin sealing by the transfer molding or similar method is performed, the hollow portion that houses comb-shaped electrodes collapses to possibly damage an electrical performance of the comb-shaped electrodes. Therefore, as described in FIG. 37, mineral filler (inorganic filler), such as mica, is mixed in the resin to increase a mechanical strength.

With the SAW device described in Patent Document 2, an additional electrode is necessary for forming a through electrode in a cover and bonding and laminating a SAW chip (a piezoelectric substrate formed with a comb-shaped electrode) and a cover (a terminal side piezoelectric substrate and top board). Also, when the substrates are laminated together, “warping” is generated in the substrate to possibly degrade an airtightness of a hollow portion (a chamber) that houses the comb-shaped electrode. Furthermore, since the substrates (wafers) made of an identical material (a piezoelectric substrate) are laminated together, a production cost of a piezoelectric component possibly increases. Furthermore, in order to ensure a low-profile piezoelectric component, thinning the substrate (the wafer) is indispensable; however, its achievement has been extremely difficult.

Additionally, with the SAW device described in Patent Document 3, silica filler is added to a photosensitive resin constituting a second resin portion (a ceiling portion) to improve the elastic modulus. However, an average size of the added filler is from 0.01 μm to 8 μm, which is large; therefore, a sufficient effect of a molding-pressure resistance cannot be obtained. The SAW device disclosed in Patent Document 4 using mica as filler has a possibility of inaccurate patterning caused by an unevenness of exposure due to the mica mixed filler when the photolithographic process is employed.

### Solutions to the Problems

The present invention is to provide a novel structure of a piezoelectric device for solving various problems including the above-described problems and a method for manufacturing the same. Its representative configuration is described as follows. To facilitate understanding the invention, reference numerals of the corresponding embodiment are attached.

(1) A piezoelectric device according to the present invention includes a piezoelectric substrate 1, comb-shaped electrodes 2, lead-out wirings 3, an outer surrounding wall layer 6, and a top board 7. The comb-shaped electrodes 2 are formed on a principal surface of the piezoelectric substrate. The lead-out wirings 3 are connected to the comb-shaped electrodes and are disposed to extend to an outer edge of the piezoelectric substrate 1. The outer surrounding wall layer 6 is arranged surrounding an outer periphery of the piezoelectric substrate including the lead-out wirings and forms a hollow portion that serves as an operation space for the comb-shaped electrodes. The top board 7 bridges the outer surrounding wall layer to seal the hollow portion. The top board 7 is constituted of a heat resistant resin that is mixed with filler of an inorganic material to improve a mechanical strength. The lead-out wiring 3 is formed on each of paired opposing side surface sides of the outer surrounding wall layer. A metal plating layer 10′ is formed to be insulated into a plurality of partitions and formed across paired opposing side surfaces of the outer surrounding wall layer, a top surface of the top board connected to the paired opposing side surfaces of the outer surrounding wall layer, and the outer edge of the piezoelectric substrate connected to the paired opposing side surfaces of the outer surrounding wall layer of the piezoelectric substrate. The metal plating layer 10′ is electrically connected to the lead-out wiring 3 in the outer edge of the piezoelectric substrate 1 to provide the metal plating layer on the top surface of the top board as a mounting terminal 11 and to provide the metal plating layer on the side surface of the outer surrounding wall layer as a side surface wiring 10 configured to connect the lead-out wiring to the mounting terminal.

(2) The present invention includes an inclined surface gradually and smoothly curving from the top board up to the outer surrounding wall layer 6 on the paired opposing side surfaces of the outer surrounding wall layer 6 and the side surface of the top board connected to the paired opposing side surfaces of the outer surrounding wall layer in the above-described (1).

(3) The present invention includes a stepped surface bending in a staircase pattern from the top board through the outer surrounding wall layer 6 to the outer edge of the piezoelectric substrate on the paired opposing side surfaces of the outer surrounding wall layer 6 and the side surface of the top board connected to the paired opposing side surfaces of the outer surrounding wall layer in the above-described (1).

(4) The present invention includes a vertical surface that is flush from the top board 7 through the outer surrounding wall layer 6 to a same plane with the outer edge of the piezoelectric substrate 1 on the paired opposing side surfaces of the outer surrounding wall layer 6 and the side surface of the top board 7 connected to the paired opposing side surfaces of the outer surrounding wall layer 6 in the above-described (1).

(5) The present invention uses a polyimide as the heat resistant resin, and a white mica as the inorganic filler described in the above-described (1).

(6) The present invention includes a solder flow preventing layer 31 on the side surface including a peripheral area of the mounting terminal 11 disposed on the top board 7 up to the metal plating layer 10′ included in the outer edge of the piezoelectric substrate 1 described in the above-described (1).

(7) The present invention disposes the solder flow preventing layer 31 described in the above-described (6) on the top board 7 except for the peripheral area of the mounting terminal 11 and a whole surface of the side surface.

(8) The present invention independently disposes the solder flow preventing layer 31 described in the above-described (6) for each of the mounting terminals 11.

(9) The present invention is constituted by forming a barrier metal layer over the mounting terminal 11 described in the above-described (6).

(10) The present invention includes a collapse preventing layer 34 for preventing the hollow portion from collapsing in a region avoiding the mounting terminal 11 on the top surface of the top board 7 described in the above-described (1) or (6).

(11) In the present invention, the collapse preventing layer 34 described in the above-described (10) is a metal layer.

(12) In the present invention, the collapse preventing layer 34 described in the above-described (10) is a thermosetting resin layer.

(13) A method for manufacturing a piezoelectric device according to the present invention includes an electrode forming step, an operation space forming step, a top board arranging step, a top board patterning step, a metal plating layer forming step, and a separating step. The electrode forming step forms comb-shaped electrodes 2 on a principal surface of a piezoelectric wafer constituting piezoelectric substrates 1 and lead-out wirings 3 connected to the comb-shaped electrodes and disposed to extend to outer edges of the piezoelectric substrates, on each of paired opposing side surface sides of the piezoelectric substrates 1. The operation space forming step arranges outer surrounding wall layers 6 for forming hollow portions that serve as operation spaces for the comb-shaped electrodes by surrounding outer peripheries of the piezoelectric substrates including the lead-out wirings. The top board arranging step seals the hollow portions by top boards made of a heat resistant resin plate mixed with inorganic filler bridging the outer surrounding wall layers 6 with peripheral edges. The top board patterning step separates the top board 7 into a pattern per SAW device of an individual chip. The metal plating layer forming step forms metal plating layers 10′ in a plurality of partitions across paired opposing side surfaces of the outer surrounding wall layers, top surface of the top board connected to the paired opposing side surfaces of the outer surrounding wall layers, and the outer edges of the piezoelectric substrates connected to the paired opposing side surfaces of the outer surrounding wall layers of the piezoelectric substrates. The separating step divides the piezoelectric wafer that is laminated with the top board into individual SAW devices after going through each of the steps. By being electrically connected to the lead-out wirings 3 in the outer edge of the piezoelectric substrate 1 using the metal plating layer 10′, the metal plating layer on the top surface of the top board provides mounting terminals 11, and the metal plating layers on the side surface of the outer surrounding wall layer provides side surface wirings 10 configured to connect the lead-out wirings to the mounting terminals.

(14) The method for manufacturing a SAW device according to the present invention uses a cutting method with a dicing blade having a taper angle as the top board patterning step in the above-described (13).

(15) The method for manufacturing the piezoelectric device according to the present invention uses a photolithographic process using an exposure mask as the top board patterning step in the above-described (13).

(16) The method for manufacturing the piezoelectric device according to the present invention uses a polyimide as the heat resistant resin plate, and a white mica as the inorganic filler in the above-described (13).

(17) The method for manufacturing the piezoelectric device according to the present invention includes a solder flow preventing layer forming step of forming a solder flow preventing layer 31 on the top surface of the top board 7 avoiding the mounting terminal 11, and the side surface up to the metal plating layer 10′ included in the outer edge of the piezoelectric substrate 1 after the metal plating layer forming step of forming the metal plating layer 10′.

(18) The method for manufacturing the piezoelectric device according to the present invention disposes the solder flow preventing layer 31 described in the above-described (17) on the top board 7 except for a peripheral area of the mounting terminal 11 and a whole surface of the side surface.

(19) The method for manufacturing the piezoelectric device according to the present invention independently disposes the solder flow preventing layer 31 described in the above-described (17) for each of the mounting terminals 11.

(20) The method for manufacturing the piezoelectric device according to the present invention includes a barrier metal forming step of forming a barrier metal layer over the mounting terminal 11 described in the above-described (17).

(21) The method for manufacturing the piezoelectric device according to the present invention includes a collapse preventing layer forming step of forming a collapse preventing layer 34 for preventing the hollow portion from collapsing in a region avoiding the mounting terminal 11 on the top surface of the top board 7 described in the above-described (13).

(22) The present invention uses a metal layer as the collapse preventing layer 34 described in the above-described (21).

(23) The present invention uses a thermosetting resin layer as the collapse preventing layer 34 described in the above-described (21).

(24) The present invention is not limited to the above-described configuration and various modifications are allowed without departing the technical idea of the present invention.

### Effects of the Invention

With the piezoelectric device and the method for manufacturing the same according to the above-described present invention, a simple process allows to form the mounting terminal (the component terminal of this device) at a desired position without a need for setting a substrate surface height with a conventional electrode column, solder ball, or solder bump, thus ensuring obtaining a piezoelectric device at a low cost.

When using it as a substrate built-in component described in the above-described FIG. 38, the need for the solder ball or the solder bump on the mounting terminal is eliminated. Thus, Cu plating is allowed for connection.

Furthermore, since the mounting terminals are formed in a resin portion constituting the top layer, which is large in area size, positions of the mounting terminals are arbitrarily selectable. Thus the mounting terminals can be disposed at the positions where a customer desires.

Furthermore, forming the wiring (the side surface wiring) that connects the comb-shaped electrode portion to the mounting terminal in a sidewall portion of the piezoelectric device surely strengthens a sealing structure of a bonding portion between the outer surrounding wall layer and the top layer. Therefore, the airtightness of the hollow portion improves.

Not requiring a patterning process that forms an opening in the top layer for forming a mounting electrode allows a significantly simplified manufacturing process. A mechanical processing by a dicing blade or similar tool can be used for processing the top layer. Employing the mechanical processing allows to avoid a generation of an atypical opening shape caused by a filler residue as described in the above-described FIG. 24.

Disposing the solder flow preventing layer avoids the decreased amount of the solder to be interposed between the mounting terminal and the terminal pad caused by the solder flowing around to the side surface wiring portion when face-down mounting it on the terminal pad, which is disposed on the surface of the mounting substrate, using the solder ball or similar means. Thereby, the solder attachment failure or instability of the clearance with the mounting substrate is prevented.

Disposing a collapse preventing layer on the top surface of the top board prevents the hollow portion that houses the comb-shaped electrode from collapsing by a pressure application in the manufacturing process of the piezoelectric device and a pressure application in the mounting process onto the substrate. Furthermore, the improved mold resistance can be expected when the piezoelectric device is modularized.

Thus, according to the present invention, the low-profiled and downsized piezoelectric device having an extremely high molding-pressure resistance can be manufactured without increasing a thickness of the component, and the piezoelectric device that allows a freedom of choice in the mounting terminal positions can be manufactured at a low cost. As described above, the present invention is not limited to the SAW devices, and is applicable to a piezoelectric device, such as a crystal controlled oscillator, and a similar piezoelectric device, such as an MEMS resonator.

### BRIEF DESCRIPTION OF THE DRAWINGS

FIG. 1 is a cross-sectional drawing describing a structure of an embodiment 1 where a piezoelectric device according to the present invention is applied to a SAW device.

FIG. 2 is a top view of the embodiment 1 where the piezoelectric device according to the present invention is applied to the SAW device illustrated in the cross-sectional drawing in FIG. 1.

FIG. 3 is a main process view describing a manufacturing method of the embodiment 1 of the SAW device applied with the piezoelectric device according to the present invention.

FIG. 4 is a process view following FIG. 3 that describes the manufacturing method of the embodiment 1 of the SAW device applied with the piezoelectric device according to the present invention.

FIG. 5 is a process view following FIG. 4 that describes the manufacturing method of the embodiment 1 of the SAW device applied with the piezoelectric device according to the present invention.

FIG. 6 is a process view following FIG. 5 that describes the manufacturing method of the embodiment 1 of the SAW device applied with the piezoelectric device according to the present invention.

FIG. 7 is a process view following FIG. 6 that describes the manufacturing method of the embodiment 1 of the SAW device applied with the piezoelectric device according to the present invention.

FIG. 8 is a process view following FIG. 7 that describes the manufacturing method of the embodiment 1 of the SAW device applied with the piezoelectric device according to the present invention.

FIG. 9 is a process view following FIG. 8 that describes the manufacturing method of the embodiment 1 of the SAW device applied with the piezoelectric device according to the present invention.

FIG. 10 is a process view following FIG. 9 that describes the manufacturing method of the embodiment 1 of the SAW device applied with the piezoelectric device according to the present invention.

FIG. 11 is a cross-sectional drawing describing a structure of an embodiment 2 where a piezoelectric device according to the present invention is applied to a SAW device.

FIG. 12 is a top view of the embodiment 2 where the piezoelectric device according to the present invention is applied to the SAW device illustrated in the cross-sectional drawing in FIG. 11.

FIG. 13 is a main process view describing a manufacturing method of the embodiment 2 of the SAW device according to the present invention.

FIG. 14 is a process view following FIG. 13 that describes the manufacturing method of the embodiment 2 of the SAW device applied with the piezoelectric device according to the present invention.

FIG. 15 is a process view following FIG. 14 that describes the manufacturing method of the embodiment 2 of the SAW device applied with the piezoelectric device according to the present invention.

FIG. 16 is a process view following FIG. 15 that describes the manufacturing method of the embodiment 2 of the SAW device applied with the piezoelectric device according to the present invention.

FIG. 17 is a process view following FIG. 16 that describes the manufacturing method of the embodiment 2 of the SAW device applied with the piezoelectric device according to the present invention.

FIG. 18 is a process view following FIG. 17 that describes the manufacturing method of the embodiment 2 of the SAW device applied with the piezoelectric device according to the present invention.

FIG. 19 is a process view following FIG. 18 that describes the manufacturing method of the embodiment 2 of the SAW device applied with the piezoelectric device according to the present invention.

FIG. 20 is a process view following FIG. 19 that describes the manufacturing method of the embodiment 2 of the SAW device applied with the piezoelectric device according to the present invention.

FIG. 21 is a process view following FIG. 20 that describes the manufacturing method of the embodiment 2 of the SAW device applied with the piezoelectric device according to the present invention.

FIG. 22 is an explanatory drawing of a state where the SAW device illustrated in FIG. 11 is mounted on a terminal pad of a mounting substrate by soldering.

FIG. 23 is an explanatory drawing of a state where solder between the mounting terminal and the terminal pad wets side surface wirings due to solder flow.

FIG. 24 is a cross-sectional drawing taken along an X-X line in FIG. 25 that describes an embodiment 3 of the SAW device applied with the piezoelectric device of the present invention.

FIG. 25 is a plan view describing the embodiment 3 of the SAW device applied with the piezoelectric device of the present invention.

FIG. 26 is a cross-sectional drawing taken along an X-X line in FIG. 27 that describes a state where a solder ball is disposed in the embodiment 3 of the SAW device applied with the piezoelectric device of the present invention.

FIG. 27 is a plan view describing the embodiment 3 of the SAW device applied with the piezoelectric device of the present invention.

FIG. 28 is a cross-sectional drawing taken along an X-X line in FIG. 29 that describes an embodiment 4 of the SAW device applied with the piezoelectric device of the present invention.

FIG. 29 is a plan view describing the embodiment 4 of the SAW device applied with the piezoelectric device of the present invention.

FIG. 30 is a process view describing a main part of a manufacturing method of the SAW device applied with the embodiment 3 of the SAW device applied with the piezoelectric device of the present invention.

FIG. 31 is a cross-sectional drawing taken along an X-X line in FIG. 32 that describes a main part of an embodiment 5 of the SAW device applied with the piezoelectric device of the present invention.

FIG. 32 is a plan view describing the main part of the embodiment 5 of the SAW device applied with the piezoelectric device of the present invention.

FIG. 33 is a cross-sectional drawing taken along an X-X line in FIG. 34 that describes the embodiment 5 of the SAW device applied with the piezoelectric device of the present invention.

FIG. 34 is a plan view describing the embodiment 5 of the SAW device applied with the piezoelectric device of the present invention.

FIG. 35 is a cross-sectional drawing describing an exemplary structure of a wafer-level chip-scale (size) package type SAW device.

FIG. 36 is an explanatory drawing of a state where the SAW device illustrated in FIG. 35 is surface mounted on a mounting substrate.

FIG. 37 is a plan view of a main part describing a problem of a top board that seals a hollow portion that houses comb-shaped electrodes.

FIG. 38 is a process view describing one exemplary process for manufacturing a substrate built-in component that includes an electronic component in a substrate.

### DESCRIPTION OF PREFERRED EMBODIMENTS

The following describes embodiments of the present invention in detail with reference to the accompanying drawings.

### Embodiment 1

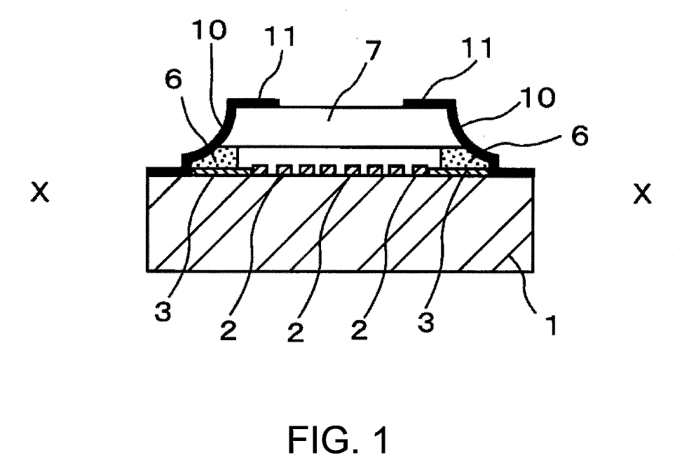

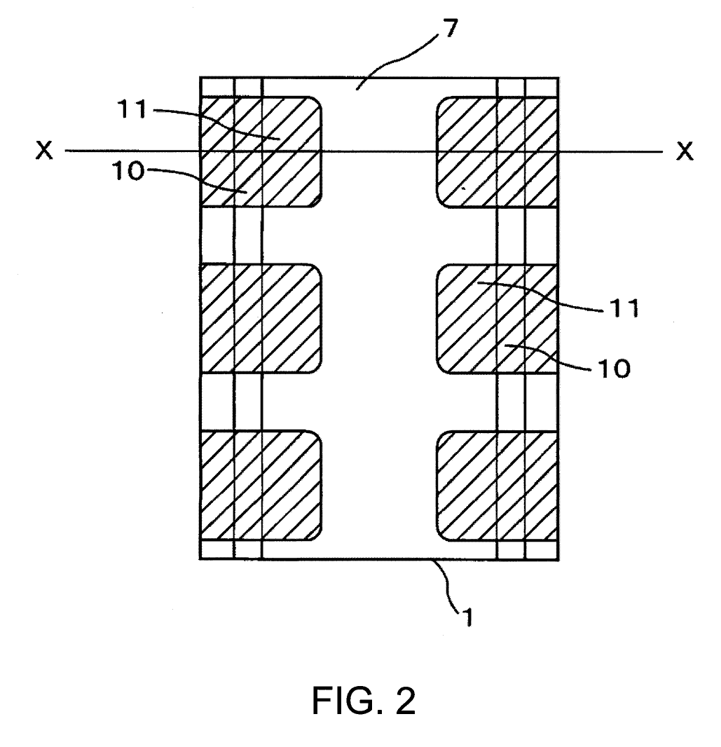

FIG. 1 is a cross-sectional drawing describing a structure of an embodiment 1 where a piezoelectric device according to the present invention is applied to a SAW device. FIG. 2 is a top view of the embodiment 1 where the piezoelectric device according to the present invention is applied to the SAW device illustrated in the cross-sectional drawing in FIG. 1. The SAW device according to the embodiment 1 uses lithium tantalite as a piezoelectric substrate 1. The SAW device includes comb-shaped electrodes (IDT) 2 on a principal surface of this piezoelectric substrate 1 and lead-out wirings 3 connected to these comb-shaped electrodes 2 and disposed to extend to outer edges of the piezoelectric substrate. For the piezoelectric substrate 1, for example, a crystal blank and lithium niobate can also be used. Here, the use of the lithium tantalite is described. Surrounding an outer periphery of the piezoelectric substrate including the lead-out wiring 3, an outer surrounding wall layer 6 that forms a hollow portion is formed. The hollow portion serves as an operation space for the comb-shaped electrodes 2. A top board 7 is secured with the end portion peripheral edges bridging the outer surrounding wall layer 6 to seal the hollow portion (a chamber), which serves as the operation space for the comb-shaped electrodes 2. The top board 7 is constituted of a heat resistant resin that has an improved mechanical strength by mixing filler of an inorganic material. In this embodiment, white mica is used as the filler.

As illustrated in FIG. 1 and FIG. 2, in the SAW device in this embodiment, the three lead-out wirings 3 of the comb-shaped electrodes 2 are formed in each of paired opposing side surface sides (right and left sides in the direction of a paper surface in FIG. 2) of the outer surrounding wall layer 6. As illustrated in FIG. 1, the SAW device in this embodiment includes inclined surfaces gradually and smoothly curving from side surfaces of the top board 7 to the outer surrounding wall layer 6. The inclined surfaces are on the paired opposing side surfaces of the outer surrounding wall layer 6 and side surfaces of the top board 7 connected to the paired opposing side surfaces of the outer surrounding wall layer 6. Metal plating layers are formed across the pair of side surfaces opposing in the right and left of the outer surrounding wall layer 6, top surfaces of the top board 7 connected to the paired opposing side surfaces of the outer surrounding wall layer 6, and outer edges of the piezoelectric substrate 1 connected to the paired opposing side surfaces of the outer surrounding wall layer 6 of the piezoelectric substrate 1. The metal plating layers are formed so as to be insulated into a plurality of partitions.

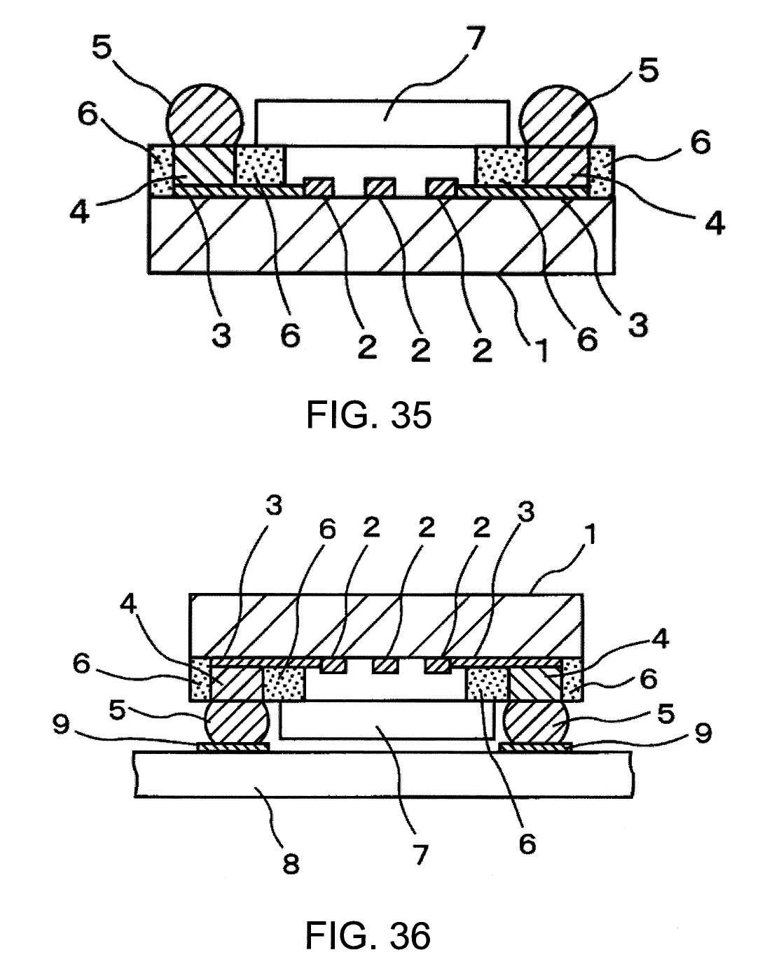

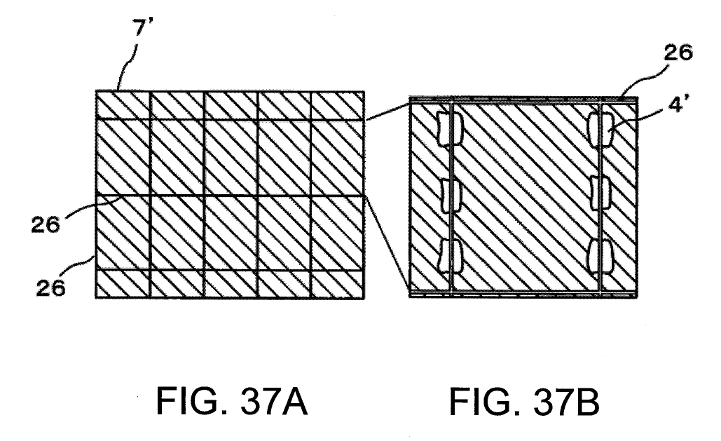

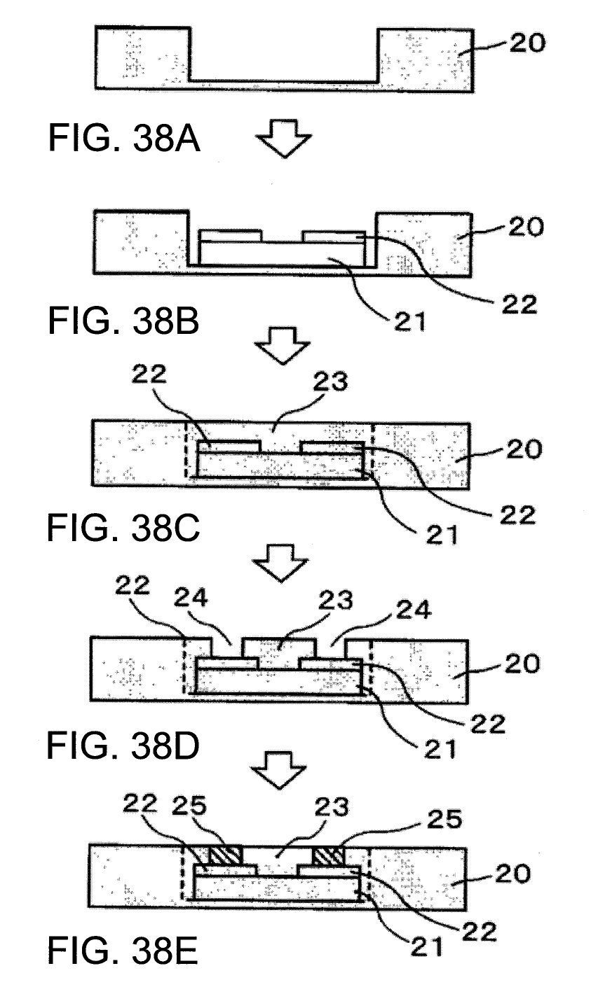

The metal plating layers are electrically connected to the lead-out wirings 3 in the outer edges of the piezoelectric substrate 1. The metal plating layers on the top surfaces of the top board 7 provides mounting terminals 11. The metal plating layers on the side surfaces of the outer surrounding wall layer provides side surface wirings 10, which connect the lead-out wirings 3 to the mounting terminals 11. This structure eliminates the need for setting a height with respect to a substrate surface with an electrode column, a solder ball, or a solder bump on the mounting terminal 11 as illustrated in FIG. 35, thus ensuring obtaining the SAW device at a low cost. Since the solder ball or the solder bump is not used on the mounting terminal, the Cu plating is allowed for connection when using it as a substrate built-in component described in FIG. 38.

According to this embodiment, since the mounting terminals are formed in a resin portion constituting the top layer 7, which is large in area size, the positions of the mounting terminals are arbitrarily selectable. Thus, the mounting terminals can be disposed at positions where a customer desires.

According to this embodiment, forming the wiring (the side surface wiring) 10 that connects the comb-shaped electrode portion to the mounting terminal in a sidewall portion of the SAW device ensures an sealing structure of a bonding portion between the outer surrounding wall layer 6 and the top layer 7, thereby ensuring an improved airtightness of the hollow portion.

As described above, according to this embodiment, the low-profiled and downsized SAW device having an extremely high molding-pressure resistance can be manufactured without increasing a thickness of the component, and the SAW device that allows a freedom of choice in the mounting terminal positions can be manufactured at a low cost.

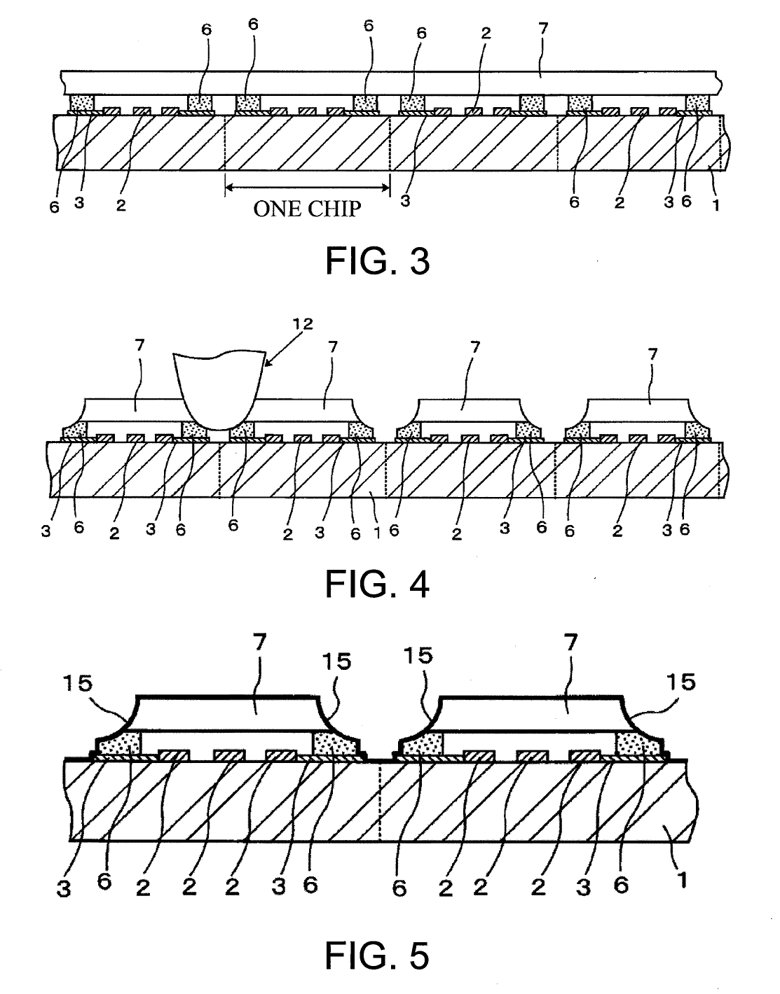

Next, a method for manufacturing the SAW device of the embodiment 1 will be described with reference to FIG. 3 to FIG. 10. On the principal surface of a lithium tantalite wafer (a piezoelectric wafer) 1 as a piezoelectric substrate, comb-shaped electrodes (IDT electrode) 2 are formed. On the paired opposing side surface sides of the outer surrounding wall layer 6, respective paired lead-out wirings 3 are formed. The pair of lead-out wirings 3 are connected to the comb-shaped electrodes 2 and disposed to extend to outer edges of the piezoelectric wafer. These comb-shaped electrodes 2 and lead-out wirings 3 are formed by a patterning of thin films of a material whose main component is any one of Al, Cu, Au, Cr, Ru, Ni, Mg, Ti, W, V, Ta, Mo, Ag, In, and Sn, a compound of these materials and oxygen, nitrogen, and silicon, or an alloy or an intermetallic compound of these materials. The thin films are laminated into multiple-layers.

Next, surrounding the outer periphery of the piezoelectric substrate 1 including the extending parts of the lead-out wirings 3, the outer surrounding wall layer 6 are arranged. The outer surrounding wall layers 6 form the hollow portion, which serves as the operation space for these comb-shaped electrodes 2. The outer surrounding wall layer 6 is formed by a photolithographic process that applies a photosensitive heat resistant resin, preferably a polyimide or an epoxy resin and uses an exposure mask. The resin that constitutes this outer surrounding wall layer 6 is preferred to be mixed with the inorganic filler, preferably the white mica, to improve the elastic modulus to increase the mechanical strength.

A heat resistant resin plate is secured covering over the outer surrounding wall layer 6 to form a constituent material of the top board 7. The heat resistant resin plate preferably is the polyimide or the epoxy resin mixed with the inorganic filler similar to the above. The constituent material of the top board 7 has the peripheral edges bridging the outer surrounding wall layer 6 that surrounds the respective comb-shaped electrodes 2 to seal the hollow portion that keeps the operation space for the comb-shaped electrodes 2. . . . FIG. 3

Next, the constituent material of the top board 7 is separated into a pattern per SAW device corresponding to an individual chip. In this embodiment, a cutting method using a dicing blade 12 with a taper angle of a curved surface as illustrated in FIG. 4 is employed for this separation into individual chips. The use of the dicing blade 12 with such taper angle forms inclined surfaces gradually and smoothly curving from the top board 7 to the outer surrounding wall layer 6 on the paired opposing side surfaces of the outer surrounding wall layer 6 and the side surfaces of the top board 7 connected to the paired opposing side surfaces of the outer surrounding wall layer 6 in the state where the top board 7 is separated into individuals corresponding to the individual chips. . . . FIG. 4

After separating the constituent material of the top board 7 into the pattern per SAW device of the individual chip, the lead-out lines 3 between the inclined surfaces, which gradually and smoothly curve from the top board 7 to the outer surrounding wall layer 6, and adjacent SAW devices of the individual chips are covered to form metal films. These metal films provide seed layers 15 for forming side surface wirings and the mounting terminals using electrolysis plating in the later process.

The seed layer 15 can be any type of metal, such as Cu and Au, as long as the metal attracts plating. In this embodiment, over a Ti film formed to be 200 Å, Cu is formed to be a thickness of 4000 Å. In the case where the resin of polyimide or similar material is used for the top layer 7, an adhesion with the metal is poor. In view of this, performing a surface roughing treatment by performing a plasma treatment or a blast processing on the resin surface as a pretreatment can improve the adhesion. According to an experiment, it is confirmed that a metal film with a satisfactory adhesion can be obtained when a polyimide-based resin is roughed to 0.3 to 0.5 μm of a surface roughness Ra by the blast processing. . . . FIG. 5

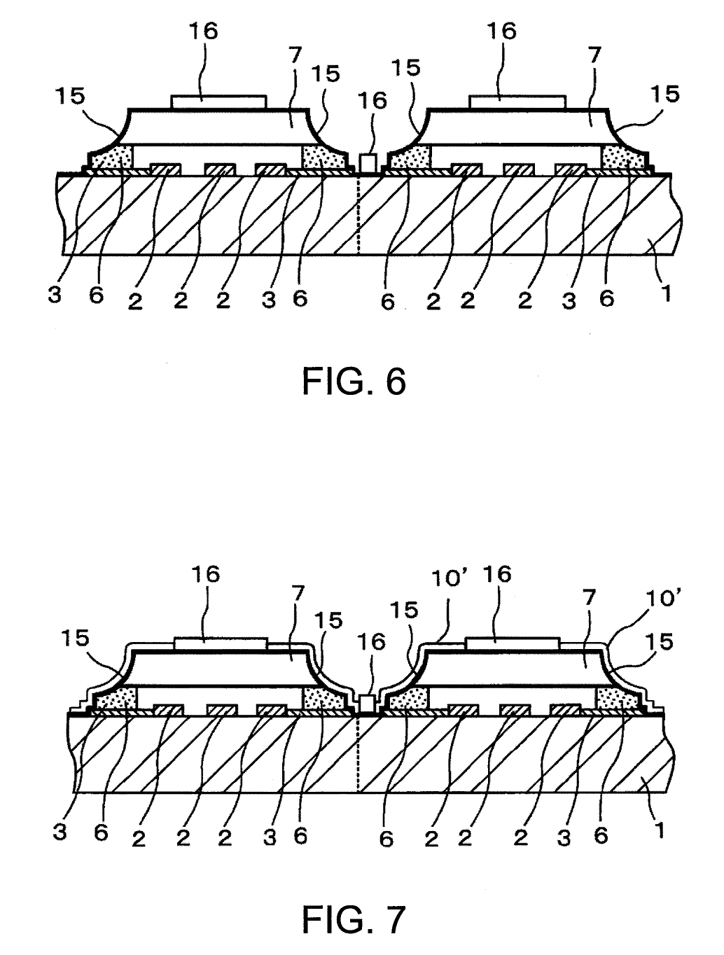

After FIG. 5, only a portion of two adjacent SAW devices are illustrated enlarged. Right and left portions of the drawings are illustrated simplified. Parts of the seed layer 15 where the above-described side surface wirings and mounting terminals are plated are exposed by the photolithographic process, which applies a photo resist over the seed layer 15 illustrated in FIG. 5 and uses the exposure mask. Parts where the plating is not needed are left with a resist 16. . . . FIG. 6

A pattern of the resist is used to grow metal plating layers 10′ over the seed layers 15 exposed in the plurality of partitions (see FIG. 2) across the paired opposing side surfaces of the outer surrounding wall layer 6 and the outer edge of the piezoelectric substrate 1 connected to the opposing surface of the outer surrounding wall layer 6 of the top board 7. For example, Ni, Au, and Cu are used as a metal for plating. In this embodiment, Cu of approximately 10 μm in thickness is formed by copper sulfate plating. A solder bump may be formed using means, such as printing, on a portion that provides the mounting terminal in this plating layer 10′ as necessary. . . . FIG. 7

While the steps described in FIG. 5 to FIG. 7 is a method for forming the plating layer 10′, which provides the mounting terminal 11 and the side surface wiring 10, using the electrolysis plating, the plating layer 10′ can also be formed by electroless plating. In the case where the electroless plating is employed, for example, sputtering film-forming may be performed selectively to a position where the plating layer 10′ is formed using a metal mask when the seed layer is formed by sputtering.

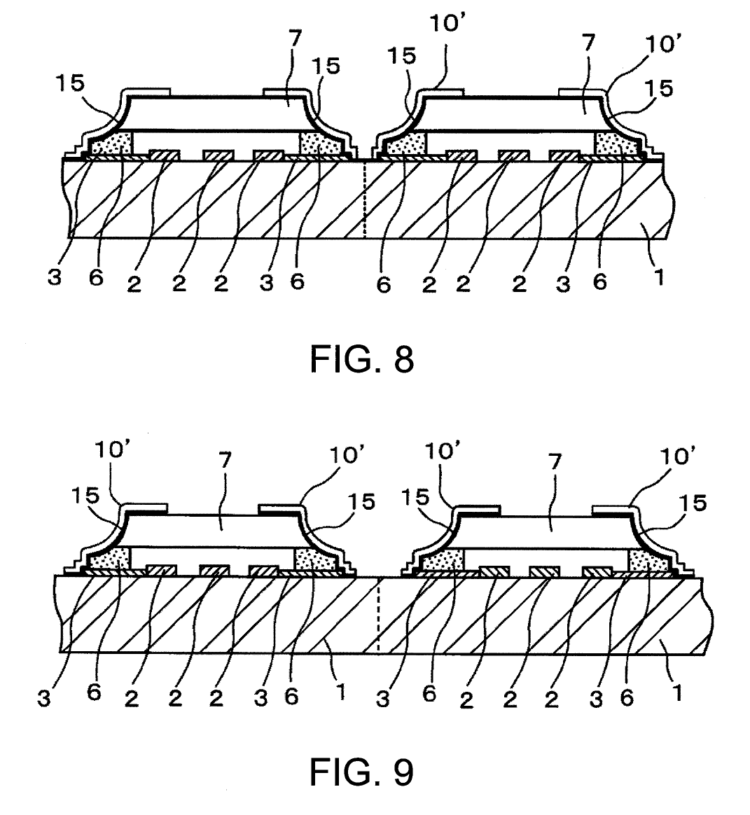

After the plating layer 10′ is formed, the resist 16 is removed by dissolving with a solution, such as acetone. At a portion where the resist is removed, the seed layer 15 exposes. . . . FIG. 8

Using an etchant, the seed layer 15 exposed on the surface of the top board 7 and the surfaces of the outer surrounding wall layer 6 and the piezoelectric substrate 1 is removed by an etching treatment. . . . FIG. 9

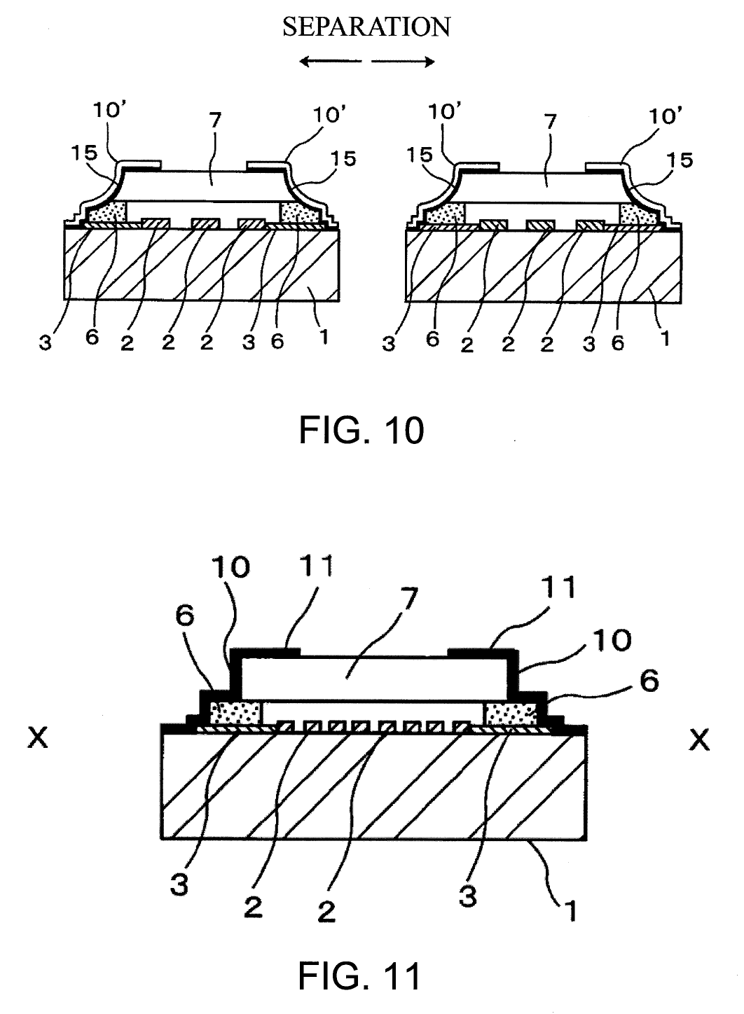

After going through each of the above-described steps, the piezoelectric substrate 1 is cut by a dicing processing at borders of individual SAW devices to separate into the SAW devices of the individual chips. The separated SAW device of individual chip is the one illustrated in the above-described FIG. 1 and FIG. 2. . . . FIG. 10

The metal plating layers on the top surface of the top board 7 are electrically connected to the lead-out wirings 3 in the outer edges of the piezoelectric substrate 1 by the metal plating layers 10′. The metal plating layers in the top surface of the top board 7 provide the mounting terminals (component terminals) 11. Since the lead-out wiring 3 and the mounting terminal 11 are configured to be connected by the side surface wiring 10, which is routed through the side surface of the outer surrounding wall layer 6, the opening processing of the outer surrounding wall layer or the opening processing of the top board described in the conventional art is not necessary. Thereby, the SAW device can be manufactured at a low cost.

Thus, the SAW device manufactured by the manufacturing method according to this embodiment forms the mounting terminals in the resin portion constituting the top layer, which is large in area size. Therefore, the positions of the mounting terminals are arbitrarily selectable. Thus, the customer can dispose the mounting terminal at a desired position. Forming the wiring (the side surface wiring) that connects the comb-shaped electrode portion to the mounting terminal in the sidewall portion of the SAW device ensures the sealing structure of the bonding portion between the outer surrounding wall layer and the top layer, thereby improving the airtightness of the hollow portion.

### Embodiment 2

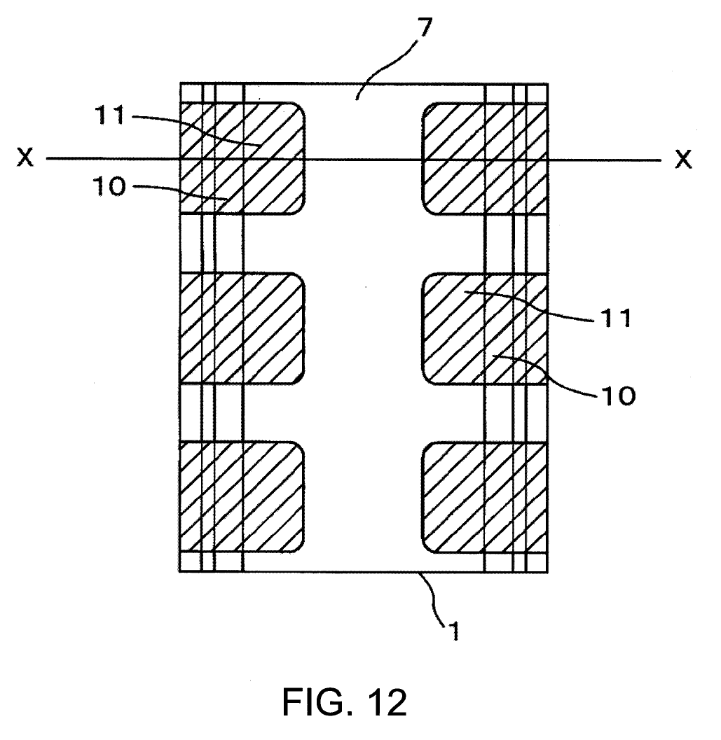

FIG. 11 is a cross-sectional drawing describing a structure of an embodiment 2 where the piezoelectric device according to the present invention is applied to a SAW device. FIG. 12 is a top view of the embodiment 2 where the piezoelectric device according to the present invention is applied to the SAW device illustrated in the cross-sectional drawing in FIG. 11. FIG. 11 corresponds to a cross-sectional surface taken along an X-X line in FIG. 12. Similarly to the embodiment 1, the SAW device according to the embodiment 2 uses the lithium tantalite as the piezoelectric substrate 1. The SAW device according to the embodiment 2 includes the comb-shaped electrodes 2 on the principal surface of this piezoelectric substrate 1 and the lead-out wirings 3 connected to these comb-shaped electrodes 2 and disposed to extend to the outer edges of the piezoelectric substrate. For the piezoelectric substrate 1, for example, the crystal blank and the lithium niobate can also be used. Here, the use of the lithium tantalite is described. Surrounding the outer periphery of the piezoelectric substrate including the lead-out wirings 3, the outer surrounding wall layer 6 that forms the hollow portion is formed. The hollow portion serves as the operation space for the comb-shaped electrodes 2. The top board 7 is secured with the end portion peripheral edges bridging these outer surrounding wall layers 6 to seal the hollow portion, which serves as the operation space for the comb-shaped electrodes 2. The top board 7 is constituted of the heat resistant resin that has the improved mechanical strength by mixing the filler of the inorganic material. In this embodiment, the white mica is used as the filler.

As illustrated in FIG. 11 and FIG. 12, with the SAW device in this embodiment, the lead-out wirings 3 of the comb-shaped electrodes are formed three each in the paired opposing side surface sides (right and left sides in the direction of a paper surface in FIG. 12) of the outer surrounding wall layer 6. As illustrated in FIG. 11, the SAW device in this embodiment includes stepped surfaces forming staircases from the side surfaces of the top board 7 to the outer surrounding wall layer 6. The stepped surfaces are on the paired opposing side surfaces of the outer surrounding wall layer 6 and side surfaces of the top board 7 connected to the paired opposing side surfaces of the outer surrounding wall layer 6. The metal plating layers are formed across the pair of side surfaces opposing in the right and left of the outer surrounding wall layer 6, the top surfaces of the top board 7 connected to the paired opposing side surfaces of the outer surrounding wall layer 6, and outer edges of the piezoelectric substrate 1 connected to the paired opposing side surfaces of the outer surrounding wall layer 6 of the piezoelectric substrate 1. The metal plating layers are formed so as to be insulated into a plurality of partitions.

The metal plating layers are electrically connected to the lead-out wirings 3 in the outer edges of the piezoelectric substrate 1. The metal plating layers on the top surfaces of the top board 7 provide the mounting terminals 11. The metal plating layers on the side surfaces of the outer surrounding wall layer provide the side surface wirings 10, which connect the lead-out wirings 3 to the mounting terminals 11. This structure eliminates the need for setting the height with respect to the substrate surface with the electrode column, the solder ball, or the solder bump on the mounting terminal 11 as illustrated in FIG. 35, thus ensuring obtaining the SAW device at a low cost. Since the solder ball or the solder bump on the mounting terminal is not used, the Cu plating is allowed for connection when using it as the substrate built-in component described in FIG. 38.

According to this embodiment, since the mounting terminals are formed in the resin portion constituting the top layer, which is large in area size, the positions of the mounting terminals are arbitrarily selectable. Thus, the mounting terminals can be disposed at positions where the customer desires.

According to this embodiment, forming the wiring (the side surface wiring) that connects the comb-shaped electrode portion to the mounting terminal in the sidewall portion of the SAW device ensures the sealing structure of the bonding portion between the outer surrounding wall layer and the top layer, thereby ensuring the improved airtightness of the hollow portion.

As described above, according to this embodiment, the low-profiled and downsized SAW device having an extremely high molding-pressure resistance can be manufactured without increasing a thickness of the component, and the SAW device that allows a freedom of choice in the mounting terminal positions can be manufactured at a low cost.

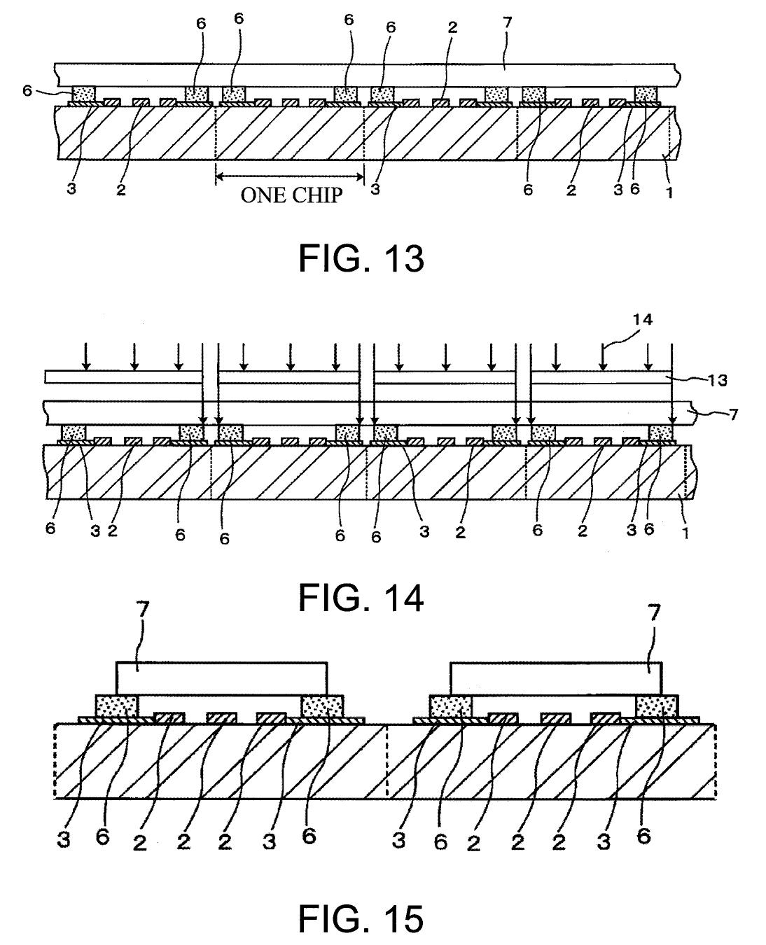

Next, a method for manufacturing the SAW device of the embodiment 1 will be described with reference to FIG. 13 to FIG. 21. Similarly to the embodiment 1, on the principal surface of the lithium tantalite wafer (the piezoelectric wafer) 1 as the piezoelectric substrate, the comb-shaped electrodes (IDT electrode) 2 are formed. On the paired opposing side surface sides of the outer surrounding wall layer 6, respective paired lead-out wirings 3 are formed. The pair of lead-out wirings 3 are connected to the comb-shaped electrodes 2 and disposed to extend to the outer edges of the piezoelectric wafer. These comb-shaped electrodes 2 and lead-out wirings 3 are formed by the patterning of thin films of a material whose main component is any one of Al, Cu, Au, Cr, Ru, Ni, Mg, Ti, W, V, Ta, Mo, Ag, In, and Sn, the compound of these materials and oxygen, nitrogen, and silicon, or the alloy or the intermetallic compound of these materials. The thin films are laminated into multiple-layers.

Next, surrounding the outer periphery of the piezoelectric substrate 1 including the extending parts of the lead-out wirings 3, the outer surrounding wall layer 6 is arranged. The outer surrounding wall layers 6 form the hollow portion, which serves as the operation space for these comb-shaped electrodes 2. The outer surrounding wall layer 6 is formed by the photolithographic process that applies the photosensitive heat resistant resin, preferably the polyimide or the epoxy resin and uses the exposure mask. The resin that constitutes this outer surrounding wall layer 6 is preferred to be mixed with the inorganic filler, preferably the white mica, to improve the elastic modulus to increase the mechanical strength.

The photosensitive heat resistant resin plate material is secured covering over the outer surrounding wall layer 6 to form a constituent material of the top board 7. The photosensitive heat resistant resin plate material preferably is the polyimide or the epoxy resin mixed with the inorganic filler similar to the above. The resin plate material of the top board 7 has the peripheral edges bridging the outer surrounding wall layer 6 that surround the respective comb-shaped electrodes 2 to seal the hollow portion that keeps the operation space for the comb-shaped electrodes 2. . . . FIG. 13

Next, the constituent material of the top board 7 is separated into the pattern per SAW device corresponding to an individual chip. For this individual chip separation, the heat resistant resin plate material in an individual chip separation portion is removed by the photolithographic process. The photolithographic process uses an exposure mask 13 on the photosensitive heat resistant resin plate material that becomes the top board 7 and performs an ultraviolet exposure and a development. . . . FIG. 14

By the process employing this photolithographic process, the stepped surface in a staircase pattern is formed from the top board 7 to the outer surrounding wall layer 6 on the paired opposing side surfaces of the outer surrounding wall layer 6 and the side surfaces of the top board 7 connected to the paired opposing side surfaces of the outer surrounding wall layer 6 in the state where the top board 7 is separated into the individuals corresponding to the individual chips. . . . FIG. 15

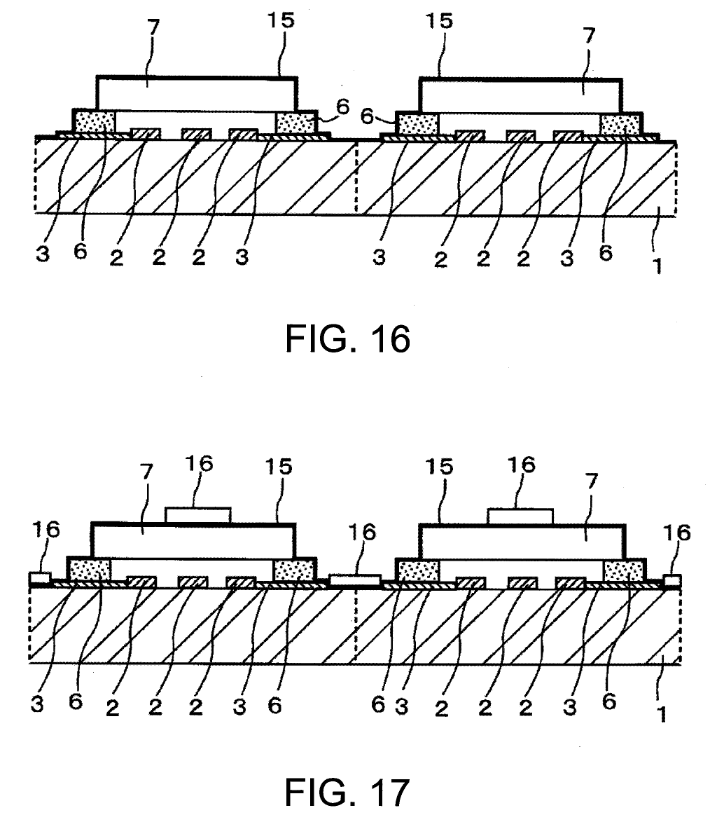

After separating the constituent material of the top board 7 into the pattern per SAW device of the individual chip, the lead-out lines 3 between the stepped surfaces in the staircase pattern from the top board 7 to the outer surrounding wall layer 6 and the adjacent SAW devices of the individual chips are covered to form the metal films. These metal films provide the seed layers 15 for forming the side surface wirings and the mounting terminals using the electrolysis plating in the later process. . . . FIG. 16

The seed layer 15 can be any type of metal, such as Cu and Au, as long as the metal attracts plating. In this embodiment, over a Ti film formed to be 200 Å, Cu is formed to be a thickness of 4000 Å. In the case where the resin of polyimide or similar material is used for the top layer, an adhesion with the metal is poor. In view of this, performing the surface roughing treatment by performing the plasma treatment or the blast processing on the resin surface as the pretreatment can improve the adhesion. According to an experiment, it has been confirmed that a metal film with a satisfactory adhesion can be obtained when the polyimide-based resin is roughed to 0.3 to 0.5 μm of the surface roughness Ra by the blast processing.

After FIG. 15, only a portion of two adjacent SAW devices are illustrated enlarged. Right and left portions of the drawings are illustrated simplified. Parts of the seed layer 15 where the above-described side surface wirings and mounting terminals are plated are exposed by the photolithographic process, which applies the photo resist over the seed layer 15 illustrated in FIG. 16 and uses the exposure mask. Parts where the plating is not needed are left with the resist 16. . . . FIG. 17

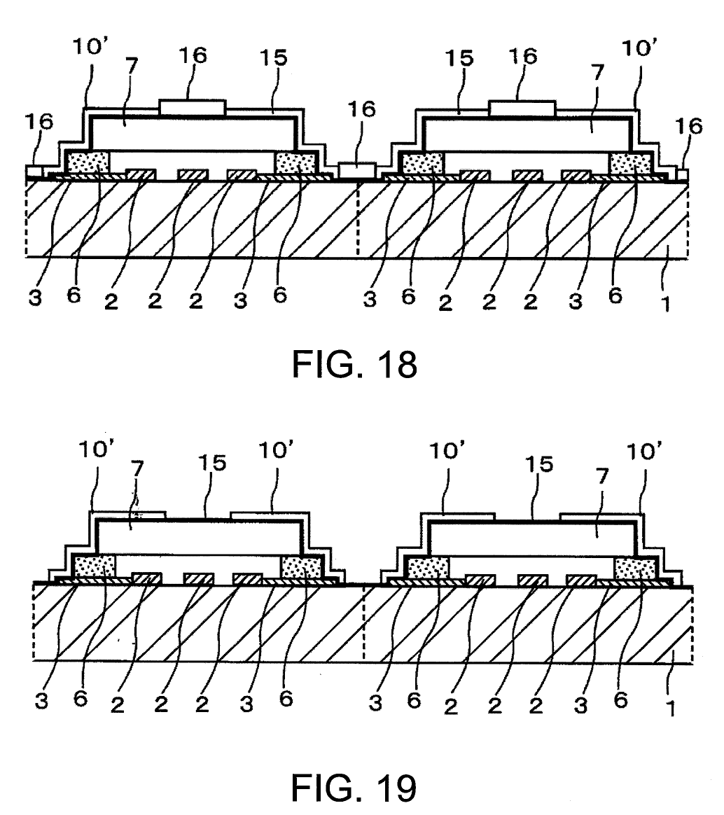

A pattern of the resist is used to grow the metal plating layers 10′ over the seed layers 15 exposed in the plurality of partitions (see FIG. 12) across the paired opposing side surfaces of the outer surrounding wall layer 6 and the outer edge of the piezoelectric substrate 1 connected to the opposing surface of the outer surrounding wall layer 6 of the top board 7. For example, Ni, Au, and Cu are used as a metal for plating. In this embodiment, Cu of approximately 10 μm in thickness is formed by the copper sulfate plating. The solder bump may be formed using means, such as printing, on the portion that provides the mounting terminal in this plating layer 10′ as necessary. . . . FIG. 18

While the steps described in FIG. 16 to FIG. 18 is the method for forming the plating layer 10′, which provides the mounting terminal 11 and the side surface wiring 10, using the electrolysis plating, the plating layer 10′ can also be formed by the electroless plating. In the case where the electroless plating is employed, for example, sputtering film-forming may be performed selectively to the position where the plating layer 10′ is formed using the metal mask when the seed layer is formed by sputtering.

After the plating layer 10′ is formed, the resist 16 is peeled off with a release agent or removed by dissolving with a solution, such as acetone. At a portion where the resist is removed, the seed layer 15 exposes. . . . FIG. 19

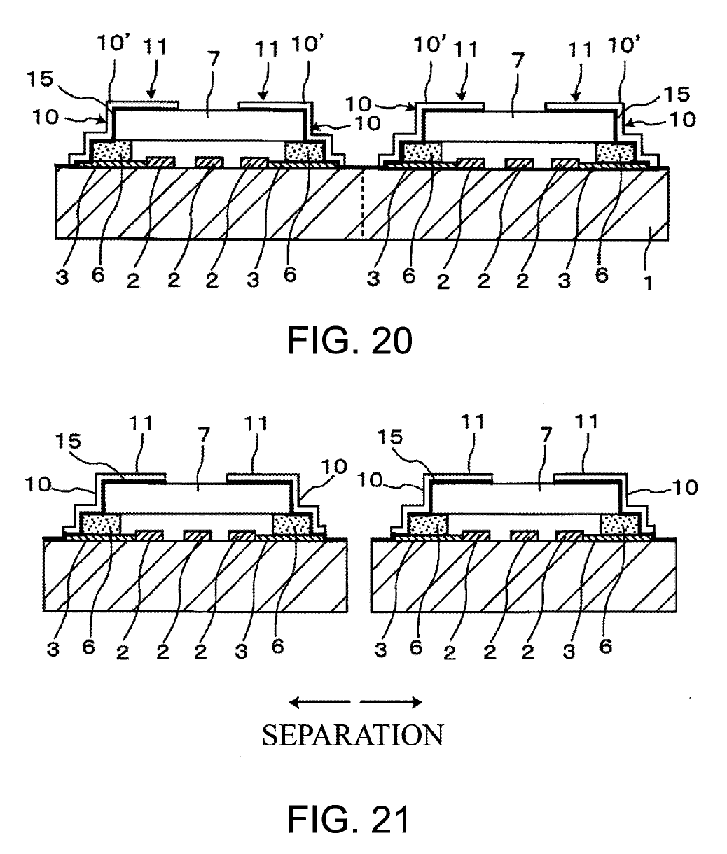

Using the etchant, the seed layer 15 exposed on the surface of the top board 7 and the surfaces of the outer surrounding wall layer 6 and the piezoelectric substrate 1 is removed by the etching treatment. . . . FIG. 20

After going through each of the above-described steps, the piezoelectric substrate 1 is cut by the dicing processing at borders of individual SAW devices to separate into the SAW devices of the individual chips. The separated SAW device of individual chip is the one illustrated in the above-described FIG. 1 and FIG. 2. . . . FIG. 21

The metal plating layers on the top surface of the top board 7 are electrically connected to the lead-out wirings 3 in the outer edges of the piezoelectric substrate 1 by the metal plating layers 10′. The metal plating layers in the top surface of the top board 7 provide the mounting terminals 11. Since the lead-out wiring 3 and the mounting terminal 11 are configured to be connected by the side surface wiring 10, which is routed through the side surface of the outer surrounding wall layer 6, the opening processing of the outer surrounding wall layer or the opening processing of the top board described in the conventional art is not necessary. Thereby, the SAW device can be manufactured at a low cost.

Thus, the SAW device manufactured by the manufacturing method according to this embodiment forms the mounting terminals in the resin portion constituting the top layer, which is large in area size. Therefore, the positions of the mounting terminals are arbitrarily selectable. Thus, the customer can dispose the mounting terminal at a desired position. Forming the wiring (the side surface wiring) that connects the comb-shaped electrode portion to the mounting terminal in the sidewall portion of the SAW device ensures the sealing structure of the bonding portion between the outer surrounding wall layer and the top layer, thereby improving the airtightness of the hollow portion.

The side surface wiring 10 electrically connects the lead-out line 3 extracted to the peripheral edge of the piezoelectric substrate 1 via the side surface of the outer surrounding wall layer 6 from the side surface of the top board 7. The plating layer is for forming the mounting terminal (the component terminal) 11 on the top surface of the top board 7. While in each of the embodiments described above, the side surface wiring 10 and the plating layer are “the inclined surface gradually and smoothly curving” in the embodiment 1 and “the stepped surface bending in a staircase pattern” in the embodiment 2, the present invention is not limited to these. “The side surface wiring 10 may be formed on a vertical side surface that is made by the side surface of the top board 7 that is vertically flush on a same plane with the side surface of the outer surrounding wall layer 6.

The processing to make the above-described flush verticality on a same plane can be formed by a selection of a blade shape of the dicing blade described in the embodiment 1 or patterning from the top board 7 to the outer surrounding wall layer 6 by the photolithographic process described in the embodiment 2.

### Embodiment 3

For example, when the SAW device according to the embodiment 2 of the present invention illustrated in the above-described FIG. 11 is mounted on the mounting substrate, it will be considered the case where the solder ball is disposed on the terminal (the component terminal) of the device to perform a solder deposit on the terminal pad of the mounting substrate. In the SAW device illustrated in FIG. 11, the mounting terminal (the component terminal) 11 can be disposed on the mounting terminal 11 constituted of the metal layer on the top board 7 without using a plating pillar or a solder bump. That is, on the top board 7, the plating pillar or the solder bump is not formed at a securing position.

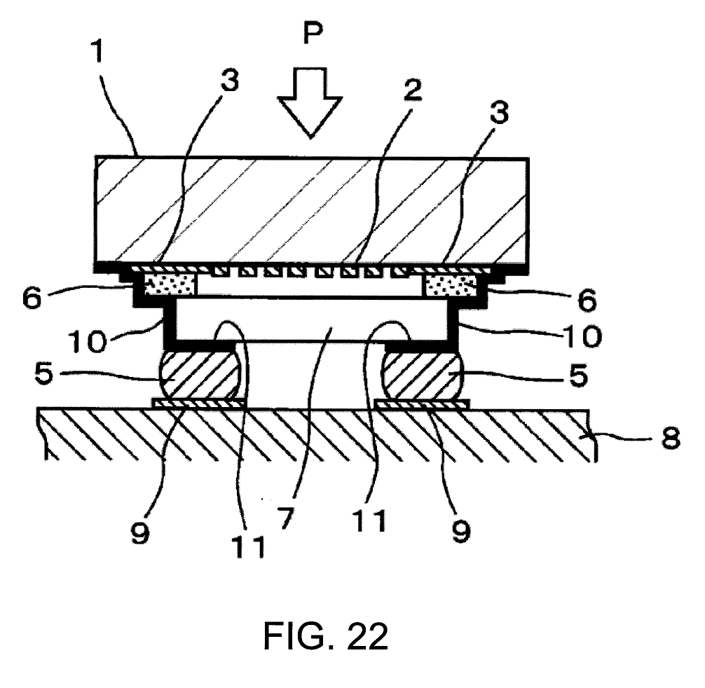

FIG. 22 is an explanatory drawing of a state where the SAW device illustrated in FIG. 11 is mounted on the terminal pad of the mounting substrate by soldering. First, the solder balls 5 are installed on the mounting terminals 11 of the SAW device. The solder balls 5 can be disposed on the mounting terminals 11 using a solder ball distribution device.

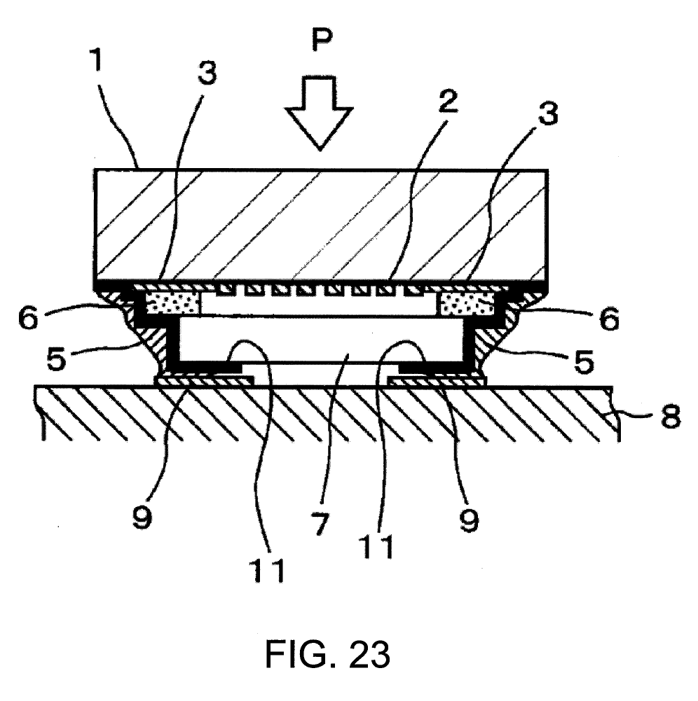

When the SAW device installed with the solder balls 5 is mounted on the mounting substrate 8, a mounting device is used to position the solder ball 5 on a terminal pad 9 formed on the mounting terminal 11 as illustrated in FIG. 22, and then the SAW device is passed through a reflow furnace. While passing through the reflow furnace, the solder ball 5 melts to deposit the mounting terminal 11 on the terminal pad 9. However, at this time, a solder flow possibly occurs to cause the melted solder to wet up to the side surface wiring 10 and possibly generate a phenomenon in which a necessary amount of the solder cannot be kept between the mounting terminal 11 and the terminal pad 9. FIG. 23 is an explanatory drawing of a state where the solder between the mounting terminal 11 and the terminal pad 9 wets the side surface wirings caused by the solder flow. As a result of the decreased amount of the solder between the mounting terminal 11 and the terminal pad 9, there is a possibility of an occurrence of a conduction failure or a non-uniform interval between the mounting terminal 11 and the terminal pad 9. This embodiment is configured to prevent such solder flow from occurring.

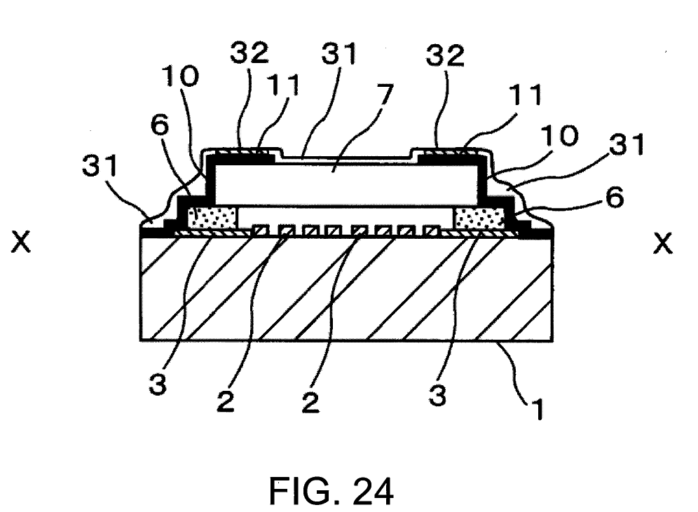

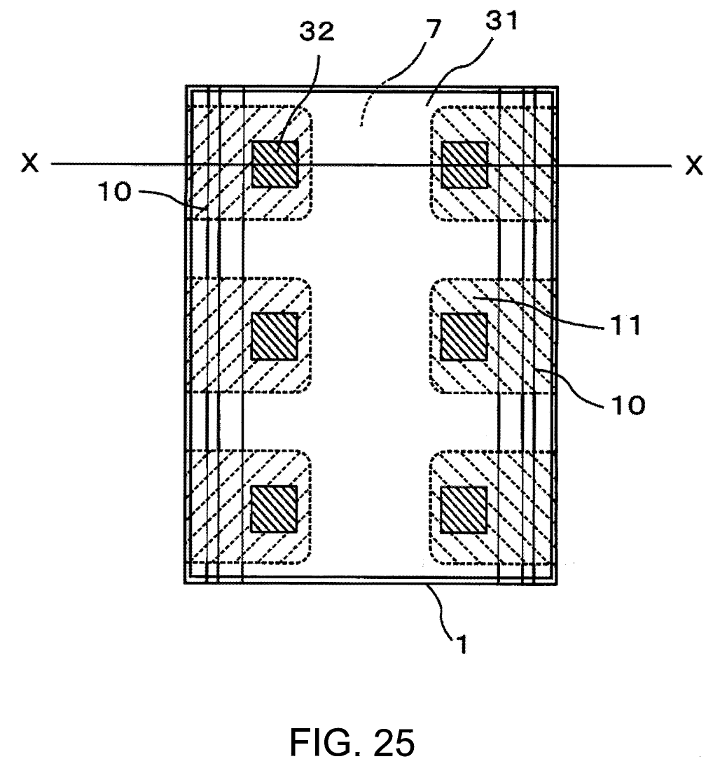

FIG. 24 is a cross-sectional drawing taken along an X-X line in FIG. 25 that describes a SAW device applied with an embodiment 3 of the piezoelectric device of the present invention that includes a solder flow preventing layer. FIG. 25 is a plan view of the SAW device applied with the embodiment 3 of the piezoelectric device of the present invention that includes the solder flow preventing layer. In FIG. 24 and FIG. 25, identical functional portions to the drawings of each of the above-described embodiments are designated with the identical reference numerals. The reference numeral 31 indicates the solder flow preventing layer and the reference numeral 32 indicates a barrier metal.

The solder flow preventing layer 31 is formed on the top board 7 except for portions where the barrier metals 32 are formed and a region from the side surface of the top board 7 and the outer surrounding wall layer 6 to the top surface outer periphery of the piezoelectric substrate 1. In FIG. 25, in order to indicate that the solder flow preventing layer 31 is positioned on the top board, the position of the peripheral edge of the solder flow preventing layer 31 is illustrated retreated from the end edge of the top board 7. The same applies to the following similar drawings.

In the SAW device according to the embodiment 3, the solder flow preventing layer 31 is disposed on a whole surface of a top portion of a disk including the side surface including the peripheral area of the mounting terminal 11 disposed on the top board 7 up to the metal plating layers 10′ included in the outer edge (the top surface outer periphery of the piezoelectric substrate 1) of the piezoelectric substrate 1. The solder flow preventing layer 31 is formed by spray-applying or spin-coat applying a solution of the thermosetting resin, such as polyimide, or liquid glass and then sintering. Alternatively, sputtering silica (SiO₂) can form the solder flow preventing layer 31.

The solder flow preventing layer 31 in portions of the mounting terminals 11 illustrated in FIG. 24 is removed using the photolithographic method to make openings as illustrated in FIG. 25. With respect to the portions that constitute the mounting terminals 11, which is exposed in these openings, nickel (Ni) plating is performed when the mounting terminal 11 is copper (Cu) plated, and gold (Au) plating is further performed as an antioxidation film, to form layers of the barrier metal 32. Gold (Au) plating is not necessary. The solder ball is disposed on this barrier metal 32 and deposited onto the terminal pad of the mounting substrate for mounting. It is also possible to directly dispose the solder ball or the solder bump on a terminal window 33 without forming the barrier metal 32. While the barrier metal 32 is not an essential configuration, taking mounting on the mounting substrate terminal using the solder into consideration, it is preferred that the barrier metal 32 is disposed.

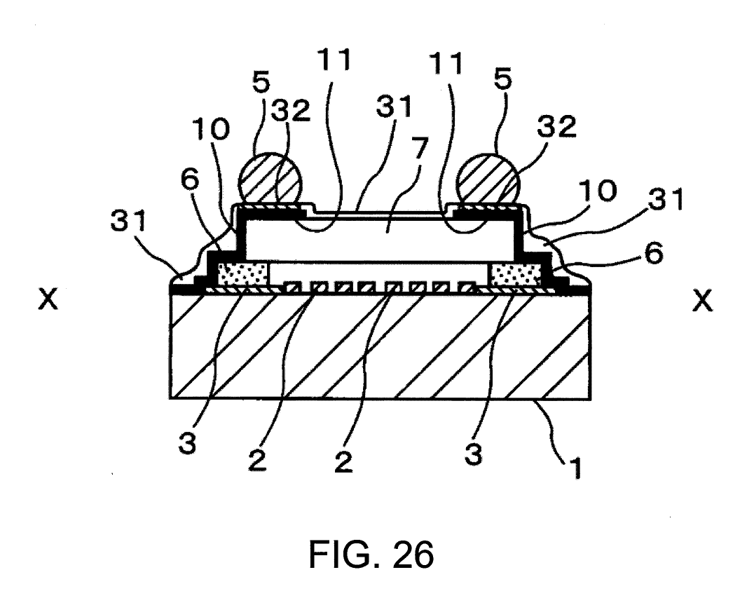

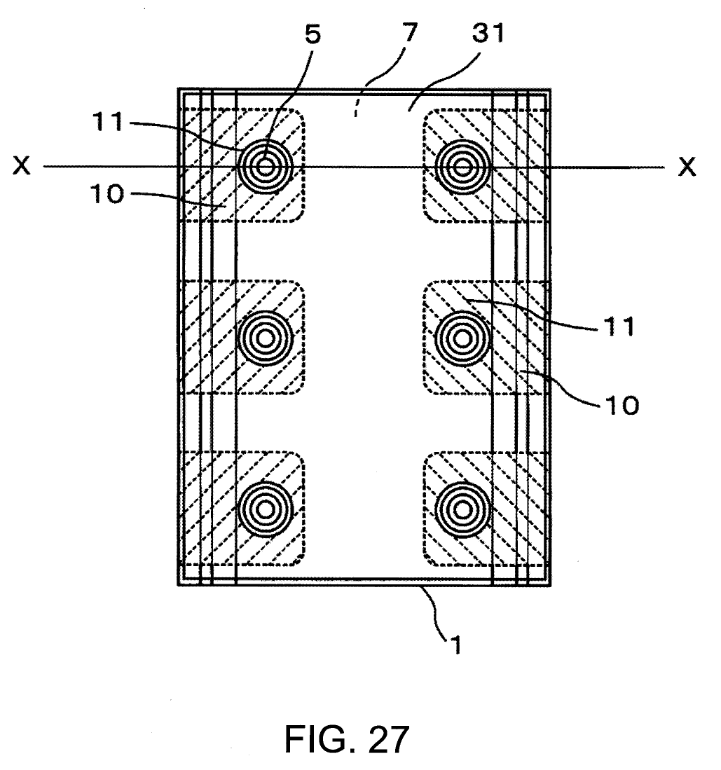

FIG. 26 is a cross-sectional drawing taken along an X-X line in FIG. 27 that describes a state where the solder ball is disposed on the mounting terminal (the component terminal) of the SAW device applied with the embodiment 3 of the piezoelectric device of the present invention including the solder flow preventing layer. FIG. 27 is a plan view of the SAW device applied with the embodiment 3 of the piezoelectric device of the present invention including the solder flow preventing layer.

In FIG. 26 and FIG. 27, the solder ball 5 is disposed on the barrier metal 32 formed on the mounting terminal 11 included on the top board 7. The solder ball 5 is disposed using the solder ball distribution device. Thus, in the case where the SAW device including the solder ball 5 is mounted on the mounting substrate 8 as described in the 22, putting the solder ball 5 on the terminal pad 9 of the mounting substrate 8 to pass through the reflow furnace performs a solder deposit on the terminal pad 9.

According to this embodiment, disposing the solder flow preventing layer 31 avoids the decreased amount of the solder that interposes between the mounting terminal 11 (the barrier metal 32) and the terminal pad 9 caused by the solder flowing around to the side surface wiring portion when face-down mounting on the terminal pad 9, which is disposed on the surface of the mounting substrate 8, using the solder ball or similar means. Thereby, the solder attachment failure or instability of the clearance with the mounting substrate is prevented.

### Embodiment 4

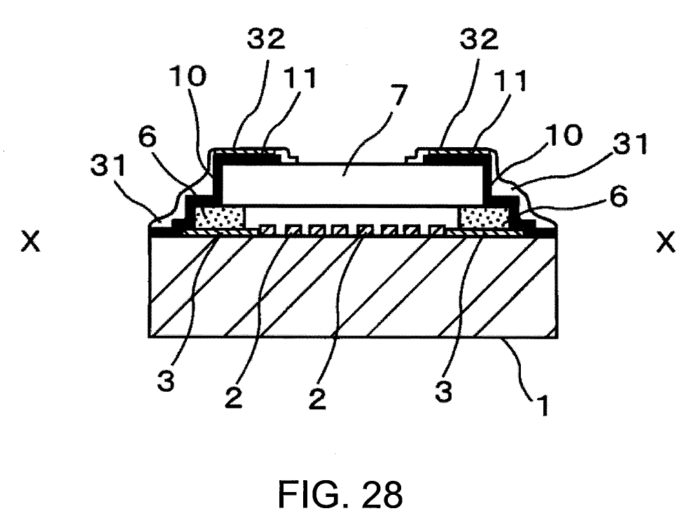

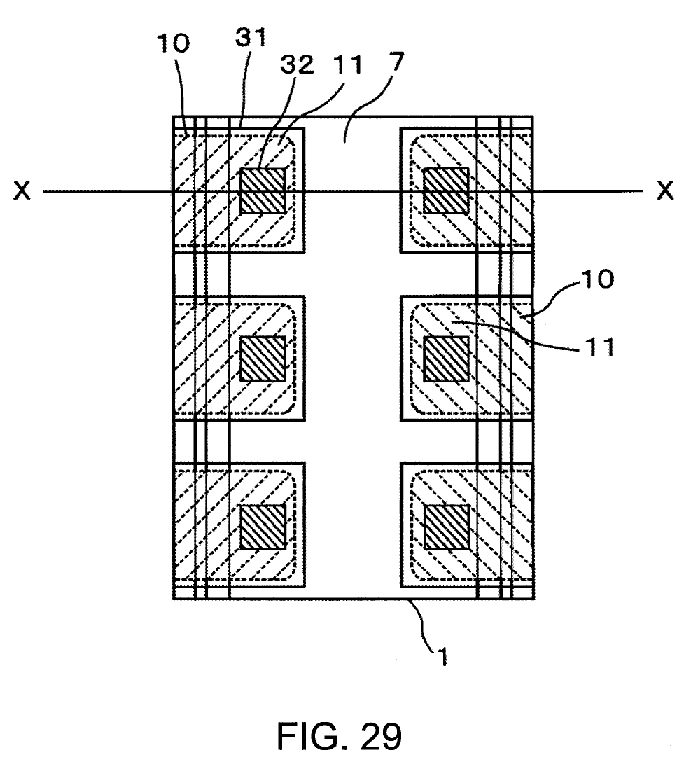

FIG. 28 is a cross-sectional drawing taken along an X-X line in FIG. 29 that describes the SAW device applied with an embodiment 4 of the piezoelectric device of the present invention. FIG. 29 is a plan view of the SAW device applied with the embodiment 4 of the piezoelectric device of the present invention. FIG. 28 corresponds to the cross-sectional surface taken along the X-X line in FIG. 29. In this embodiment, the solder flow preventing layers 31 are independently disposed for each of the mounting terminals 11 (the barrier metals 32). As illustrated in FIG. 28 and FIG. 29, the solder flow preventing layers 31 in this embodiment are individually formed in the peripheral areas of the side surface wirings 10 and the mounting terminals 11. The solder flow preventing layers 31 are not formed in portions, such as the top board 7, the outer surrounding wall layer 6, or similar portion. The barrier metal 32 and other configurations are similar to the embodiment 3.

According to this embodiment, disposing the solder flow preventing layer 31 avoids the decreased amount of the solder that is interposed between the mounting terminal 11 (the barrier metal 32) and the terminal pad 9 caused by the solder flowing around to the side surface wiring portion when face-down mounting on the terminal pad 9, which is disposed on the surface of the mounting substrate 8 using the solder ball or similar means. Thereby, the solder attachment failure or the instability of the clearance with the mounting substrate is prevented.

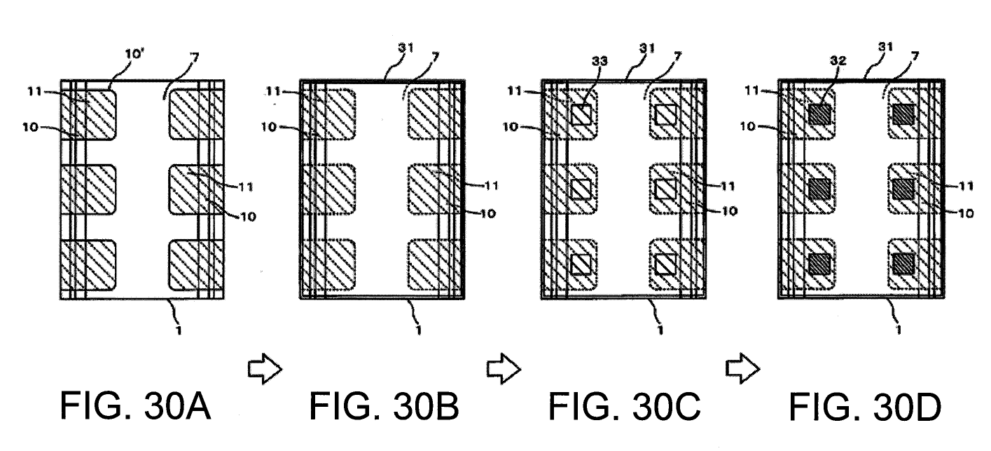

FIG. 30 is a process view describing a main part of the manufacturing method of the SAW device that is described in the embodiment 3 of the present invention that including the solder flow preventing layer. The SAW device in a state of after going through the steps described in the above-described FIG. 13 to FIG. 20 is illustrated in FIG. 30A. The plating layer 10′ constituting the mounting terminal 11 and the side surface wiring 10 from the top board 7 to the lead-out wiring is made of copper (Cu) or nickel (Ni), or an alloy of copper (Cu) and nickel (Ni).

FIG. 30B illustrates a state where a polyimide solution is spray applied and sintered to be cured to form the solder flow preventing layer 31. For the application of the polyimide solution, a spin coating or a printing method can be used besides the spray application. Not limited to the polyimide solution, other thermosetting resins or a glass coating film, silica (SiO₂) sputtering film can be employed.

FIG. 30C illustrates a state where a window (the terminal window 33) is formed in the mounting terminal forming portions. The photo resist is applied on the polyimide solder flow preventing layer 31, and then the terminal window 33 is formed by the photolithographic process that goes through an exposure to the ultraviolet light via the exposure mask including a predetermined opening and a developing process.

FIG. 30D forms the barrier metals 32 by plating nickel (Ni) on the terminal windows 33 disposed in the mounting terminal forming portions and plating gold (Au) thereafter. On these barrier metals 32, similarly to the description in FIG. 26, the solder balls are disposed to deposit and to be mounted on the terminal pads of the mounting substrate. Not forming the barrier metals, the solder balls or the solder bumps can also be directly disposed on the terminal window 33.

According to this embodiment, similarly to the embodiment 3, disposing the solder flow preventing layer 31 avoids the decreased amount of the solder that is interposed between the mounting terminal 11 (the barrier metal 32) and the terminal pad 9 caused by the solder flowing around to the side surface wiring portion when face-down mounting on the terminal pad 9, which is disposed on the surface of the mounting substrate 8 using the solder ball or similar means. Thereby, the solder attachment failure or the instability of the clearance with the mounting substrate is prevented.

### Embodiment 5

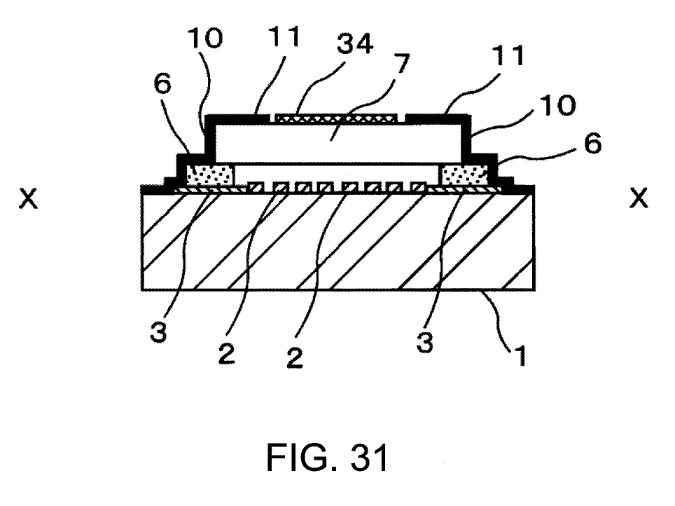

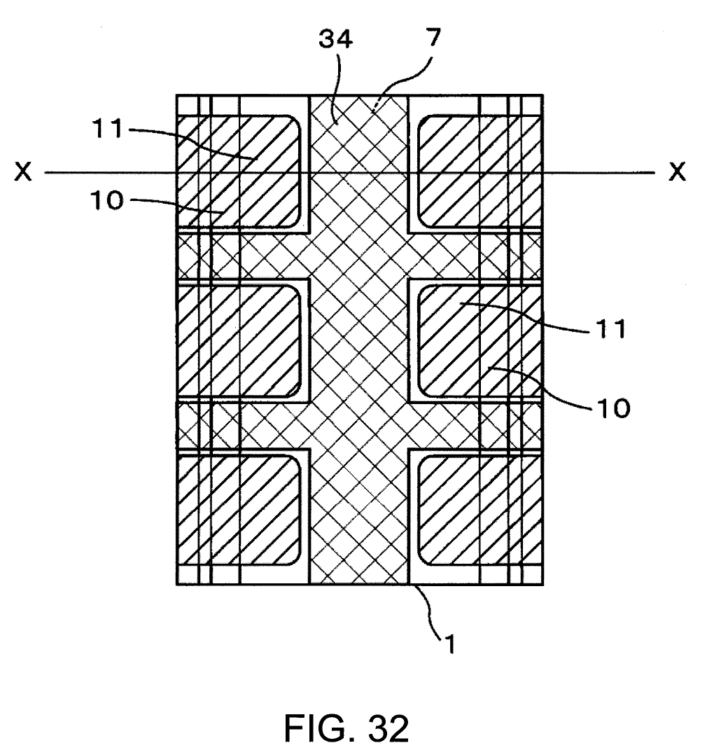

FIG. 31 is a cross-sectional drawing taken along an X-X line in FIG. 32 that describes a main part of the SAW device applied with an embodiment 5 of the piezoelectric device of the present invention. FIG. 32 is a plan view describing the main part of the SAW device applied with the embodiment 5 of the piezoelectric device of the present invention. The embodiment 5 disposes a collapse preventing layer in the top board constituting the device and the device. This is to further prevent the collapse from occurring in the operation space (the chamber, the hollow portion that houses the IDT portion) due to the pressure application in the laminating process of the top board material 7 or the mounting process to the mounting substrate described in the above-described FIG. 3 or FIG. 13. Furthermore, the improved mold resistance can be expected when the piezoelectric device is modularized.

The SAW device of this embodiment forms the plurality of side surface wirings 10 and the mounting terminals (the component terminals) 11 electrically separated across the side surface of the above-described device and the top surface of the top board 7. Also, the SAW device of this embodiment includes a collapse preventing layer 34 in a portion avoiding the above-described side surface wirings 10, and the mounting terminals (the component terminals) 11. This collapse preventing layer 34 is formed using a metal or a resin. In the case where the metal is used, the collapse preventing layer 34 is formed by plating copper (Cu), nickel (Ni), or similar material, or by evaporation or sputtering. The collapse preventing layer 34 can be simultaneously formed with the side surface wirings 10 and the mounting terminals (the component terminals) 11.

For the collapse preventing layer 34, a layer of a thermosetting resin, such as the polyimide resin, a polyester resin, and the epoxy resin, can be used. These resin solutions are applied by spraying or spinning to form the collapse preventing layer 34 in a region illustrated in FIG. 32 by the photolithographic process.

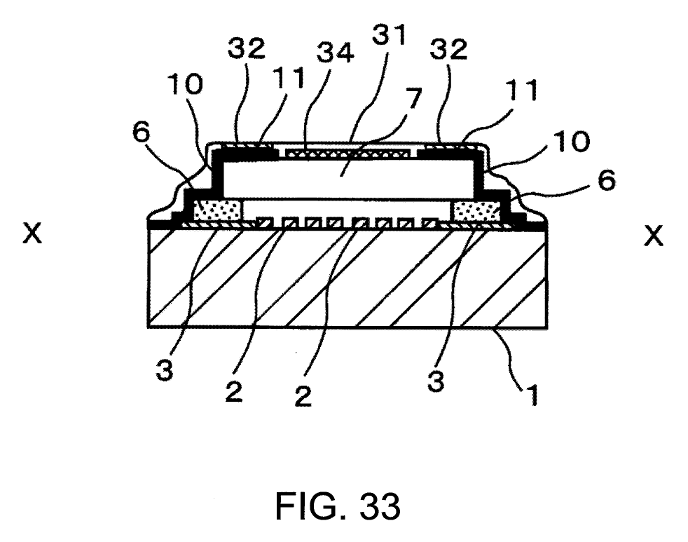

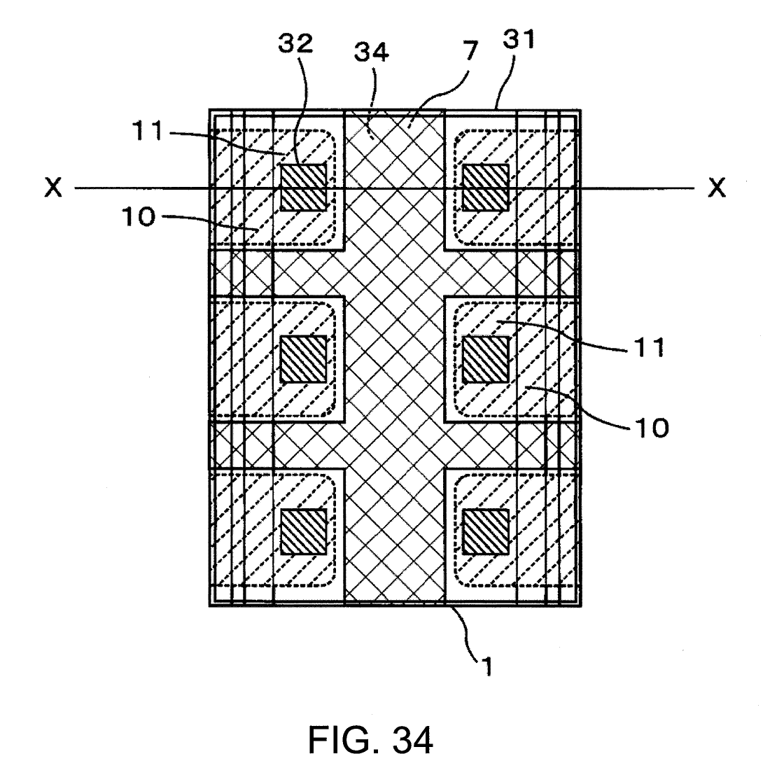

In this embodiment, the solder flow preventing layer 31 is disposed over the above-described collapse preventing layer 34, and thereafter the solder flow preventing layer 31 similar to the embodiment 3 described in FIG. 24 is formed. FIG. 33 is a cross-sectional drawing taken along an X-X line in FIG. 34 that describes the SAW device including the solder flow preventing layer 31 over the collapse preventing layer 34. FIG. 34 is a plan view of the SAW device including the solder flow preventing layer over the collapse preventing layer. As illustrated in FIG. 33 and FIG. 34, openings for the mounting terminals are formed in the solder flow preventing layer 31, and the barrier metals 32 are disposed in these openings as necessary. The solder flow preventing layer 31 can be similar to the one in the embodiment 4.

This embodiment can further prevent the operation space (the chamber, the hollow portion that houses the IDT portion) from collapsing due to the pressure application in the laminating process of the top board material or the mounting process to the mounting substrate. Disposing the solder flow preventing layer 31 similar to the ones in the above-described embodiments over this collapse preventing layer avoids the decreased amount of the solder that is interposed between the mounting terminal 11 (the barrier metal 32) and the terminal pad 9 caused by the solder flowing around to the side surface wiring portion when face-down mounting on the terminal pad 9, which is disposed on the surface of the mounting substrate 8, using the solder ball or similar means. Thereby, the solder attachment failure or the instability of the clearance with the mounting substrate is prevented.

The present invention is not limited to the SAW devices in the above-described embodiments, it is needless to say that the present invention is applicable to a crystal controlled oscillator, an MEMS resonator, and other electronic devices having similar problems.

### DESCRIPTION OF REFERENCE SIGNS

1 . . . piezoelectric substrate
2 . . . comb-shaped electrode (IDT electrode)
3 . . . lead-out wiring
4 . . . electrode column
5 . . . mounting terminal
6 . . . outer surrounding wall layer
7 . . . top board
8 . . . mounting substrate
9 . . . terminal pad
10 . . . side surface wiring
10′ . . . plating layer
11 . . . mounting terminal (component terminal)
12 . . . dicing blade
13 . . . photo mask
14 . . . ultraviolet rays
15 . . . seed layer
16 . . . resist
20 . . . component embedded substrate
21 . . . electronic component
22 . . . component terminal
23 . . . resin
24 . . . opening
25 . . . electrode column
26 . . . cut line
31 . . . solder flow preventing layer
32 . . . barrier metal
32 . . . terminal window
32 . . . collapse preventing layer

1. A piezoelectric device comprising:
a piezoelectric substrate;
comb-shaped electrodes formed on a principal surface of the piezoelectric substrate;
lead-out wirings connected to the comb-shaped electrodes, the lead-out wirings being disposed to extend to an outer edge of the piezoelectric substrate;
an outer surrounding wall layer arranged surrounding an outer periphery of the piezoelectric substrate including the lead-out wirings, the outer surrounding wall layer forming a hollow portion that serves as an operation space for the comb-shaped electrodes; and
a top board that bridges the outer surrounding wall layer to seal the hollow portion, wherein:
the top board is constituted of a heat resistant resin that is mixed with filler of an inorganic material to improve a mechanical strength,
the lead-out wiring is formed on each of paired opposing side surface sides of the outer surrounding wall layer,
a metal plating layer is formed to be insulated into a plurality of partitions, the metal plating layer being formed across paired opposing side surfaces of the outer surrounding wall layer, a top surface of the top board connected to the paired opposing side surfaces of the outer surrounding wall layer, and the outer edge of the piezoelectric substrate connected to the paired opposing side surfaces of the outer surrounding wall layer, and
the metal plating layer is electrically connected to the lead-out wiring in the outer edge of the piezoelectric substrate to provide the metal plating layer on the top surface of the top board as a mounting terminal and to provide the metal plating layer on the side surface of the outer surrounding wall layer as a side surface wiring configured to connect the lead-out wiring to the mounting terminal.

2. The piezoelectric device according to claim 1, comprising
an inclined surface gradually and smoothly curving from the top board up to the outer surrounding wall layer on the paired opposing side surfaces of the outer surrounding wall layer and the side surface of the top board connected to the paired opposing side surfaces of the outer surrounding wall layer.

3. The piezoelectric device according to claim 1, comprising
a stepped surface bending in a staircase pattern from the top board through the outer surrounding wall layer to the outer edge of the piezoelectric substrate on the paired opposing side surfaces of the outer surrounding wall layer and the side surface of the top board connected to the paired opposing side surfaces of the outer surrounding wall layer.

4. The piezoelectric device according to claim 1, comprising
a vertical surface that is flush from the top board through the outer surrounding wall layer to a same plane with the outer edge of the piezoelectric substrate on the paired opposing side surfaces of the outer surrounding wall layer and the side surface of the top board connected to the paired opposing side surfaces of the outer surrounding wall layer.

5. The piezoelectric device according to claim 1, wherein
a polyimide is used as the heat resistant resin, and a white mica is used as the inorganic filler.

6. The piezoelectric device according to claim 1, comprising
a solder flow preventing layer on the side surface including a peripheral area of the mounting terminal disposed on the top board up to the metal plating layer included in the outer edge of the piezoelectric substrate.

7. The piezoelectric device according to claim 6, wherein
the solder flow preventing layer is disposed on the top board except for the peripheral area of the mounting terminal, and a whole surface of the side surface.

8. The piezoelectric device according to claim 6, wherein
the solder flow preventing layer is independently disposed for each of the mounting terminals.

9. The piezoelectric device according to claim 6, wherein
the piezoelectric device is constituted by forming a barrier metal layer over the mounting terminal.

10. The piezoelectric device according to claim 1, comprising
a collapse preventing layer for preventing the hollow portion from collapsing in a region avoiding the mounting terminal on the top surface of the top board.

11. The piezoelectric device according to claim 10, wherein
the collapse preventing layer is a metal layer.

12. The piezoelectric device according to claim 10, wherein
the collapse preventing layer is a thermosetting resin layer.

13. (canceled)

14. (canceled)

15. (canceled)

16. (canceled)

17. (canceled)

18. (canceled)

19. (canceled)

20. (canceled)

21. (canceled)

22. (canceled)

23. (canceled)
